(19) United States
(12) Patent Application Publication
(10) Pub. No.: US 2011/0151656 A1
(43) Pub. Date: Jun. 23, 2011

(54) SEMICONDUCTOR DEVICE AND METHOD OF FABRICATING THE SAME

(75) Inventor: Yoichi FUKUSHIMA, Tokyo (JP)

(73) Assignee: Elpida Memory, Inc., Tokyo (JP)

(21) Appl. No.: 12/963,183

(22) Filed: Dec. 8, 2010

(30) Foreign Application Priority Data
Dec. 18, 2009 (JP) 2009-287801

(51) Int. Cl. H01L 21/28

(52) U.S. Cl. 438/589; 257/E21.158

(57) ABSTRACT

A method of forming a semiconductor device, the method including the following processes. A groove is formed in a semiconductor substrate. A gate electrode is formed in the groove. A boron-phosphorus silicate glass film is formed over the gate electrode. An etching process is performed using the boron-phosphorus silicate glass film as an etching stopper for preventing the gate electrode from being removed.

### BACKGROUND OF THE INVENTION

1. Field of the Invention

The present invention relates to a semiconductor device and a method of fabricating the same.

Priority is claimed on Japanese Patent Application No. 2009-287801, Dec. 18, 2009, the content of which is incorporated herein by reference.

2. Description of the Related Art

In recent years, the miniaturization of dynamic random access memory (DRAM) cells has necessitated a reduction in gate length of an access transistor (hereinafter, referred to as a “cell transistor”) of a cell array. However, as the gate length of the cell transistor decreases, a short channel effect of the cell transistor increases. Thus, the threshold voltage Vt of the cell transistor is reduced due to an increase in subthreshold current. Also, when the concentration of a substrate is increased to suppress a drop in threshold voltage Vt, junction leakage increases. As a result, deterioration of refresh characteristics of a DRAM may occur.

Japanese Unexamined Patent Application, First Publications, Nos. JP-A-2006-339476 and JP-A-2007-081095 disclose a trench-gate transistor (also referred to as a “recess channel transistor”) in which a gate electrode is buried in a trench formed in a silicon substrate. Since it is possible to sufficiently ensure an effective channel length, which is a gate length, of the trench-gate transistor, even a fine DRAM with a minimum processing dimension of about 60 nm or less may be realized.

### SUMMARY

In one embodiment, a method of forming a semiconductor device may include, but is not limited to the following processes. A groove is formed in a semiconductor substrate. A gate electrode is formed in the groove. A boron-phosphorus silicate glass film is formed over the gate electrode. An etching process is performed using the boron-phosphorus silicate glass film as an etching stopper for preventing the gate electrode from being removed.

In another embodiment, a method of forming a semiconductor device may include, but is not limited to the following processes. A boron-phosphorus silicate glass film is formed over a semiconductor substrate. A multi-layered structure comprising an oxide film is formed over the boron-phosphorus silicate glass film and the semiconductor substrate. An opening in the oxide film is formed to expose a first portion of the semiconductor substrate and a second portion of the boron-phosphorus silicate glass film. A cleaning process is performed to clean the first portion in a condition where the boron-phosphorus silicate glass film is lower in etching rate than the oxide film.

In still another embodiment, a method of forming a semiconductor device may include, but is not limited to the following processes. A groove is formed in the semiconductor substrate. A gate electrode is formed in the groove. An insulating film is formed in the groove and over the semiconductor substrate. A boron-phosphorus silicate glass film is formed in the groove and over the semiconductor substrate. A surface of the boron-phosphorus silicate glass film and a surface of the semiconductor substrate are planarized.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a fragmentary plan view illustrating a memory cell including a semiconductor device in accordance with one embodiment of the present invention;

FIG. 2A is a fragmentary cross sectional elevation view, taken along an A-A′ line of FIG. 1, illustrating a memory cell in the semiconductor device of FIG. 1;

FIG. 2B is a fragmentary cross sectional elevation view, taken along a B-B′ line of FIG. 1, illustrating a memory cell in the semiconductor device of FIG. 1;

FIG. 3A is a fragmentary cross sectional elevation view, taken along an A-A′ line of FIG. 1, illustrating a memory in a step involved in a method of forming the semiconductor device of FIGS. 1, 2A and 2B;

FIG. 3B is a fragmentary cross sectional elevation view, taken along a B-B′ line of FIG. 1, illustrating a memory in a step involved in a method of forming the semiconductor device of FIGS. 1, 2A and 2B;

FIG. 4A is a fragmentary cross sectional elevation view, taken along an A-A′ line of FIG. 1, illustrating a memory cell in a step, subsequent to the step of FIGS. 3A and 3B, involved in the method of forming the semiconductor device of FIGS. 1, 2A and 2B;

FIG. 4B is a fragmentary cross sectional elevation view, taken along a B-B′ line of FIG. 1, illustrating a memory cell in a step, subsequent to the step of FIGS. 3A and 3B, involved in the method of forming the semiconductor device of FIGS. 1, 2A and 2B;

FIG. 5A is a fragmentary cross sectional elevation view, taken along an A-A′ line of FIG. 1, illustrating a memory cell in a step, subsequent to the step of FIGS. 4A and 4B, involved in the method of forming the semiconductor device of FIGS. 1, 2A and 2B;

FIG. 5B is a fragmentary cross sectional elevation view, taken along a B-B′ line of FIG. 1, illustrating a memory cell in a step, subsequent to the step of FIGS. 4A and 4B, involved in the method of forming the semiconductor device of FIGS. 1, 2A and 2B;

FIG. 6A is a fragmentary cross sectional elevation view, taken along an A-A′ line of FIG. 1, illustrating a memory cell in a step, subsequent to the step of FIGS. 5A and 5B, involved in the method of forming the semiconductor device of FIGS. 1, 2A and 2B;

FIG. 6B is a fragmentary cross sectional elevation view, taken along a B-B′ line of FIG. 1, illustrating a memory cell in a step, subsequent to the step of FIGS. 5A and 5B, involved in the method of forming the semiconductor device of FIGS. 1, 2A and 2B;

FIG. 7A is a fragmentary cross sectional elevation view, taken along an A-A′ line of FIG. 1, illustrating a memory cell in a step, subsequent to the step of FIGS. 6A and 6B, involved in the method of forming the semiconductor device of FIGS. 1, 2A and 2B;

FIG. 7B is a fragmentary cross sectional elevation view, taken along a B-B′ line of FIG. 1, illustrating a memory cell in a step, subsequent to the step of FIGS. 6A and 6B, involved in the method of forming the semiconductor device of FIGS. 1, 2A and 2B;

FIG. 8A is a fragmentary cross sectional elevation view, taken along an A-A′ line of FIG. 1, illustrating a memory cell in a step, subsequent to the step of FIGS. 7A and 7B, involved in the method of forming the semiconductor device of FIGS. 1, 2A and 2B;

FIG. 8B is a fragmentary cross sectional elevation view, taken along a B-B′ line of FIG. 1, illustrating a memory cell in a step, subsequent to the step of FIGS. 7A and 7B, involved in the method of forming the semiconductor device of FIGS. 1, 2A and 2B;

FIG. 9A is a fragmentary cross sectional elevation view, taken along an A-A′ line of FIG. 1, illustrating a memory cell in a step, subsequent to the step of FIGS. 8A and 8B, involved in the method of forming the semiconductor device of FIGS. 1, 2A and 2B;

FIG. 9B is a fragmentary cross sectional elevation view, taken along a B-B′ line of FIG. 1, illustrating a memory cell in a step, subsequent to the step of FIGS. 8A and 8B, involved in the method of forming the semiconductor device of FIGS. 1, 2A and 2B;

FIG. 10A is a fragmentary cross sectional elevation view, taken along an A-A′ line of FIG. 1, illustrating a memory cell in a step, subsequent to the step of FIGS. 9A and 9B, involved in the method of forming the semiconductor device of FIGS. 1, 2A and 2B;

FIG. 10B is a fragmentary cross sectional elevation view, taken along a B-B′ line of FIG. 1, illustrating a memory cell in a step, subsequent to the step of FIGS. 9A and 9B, involved in the method of forming the semiconductor device of FIGS. 1, 2A and 2B;

FIG. 11A is a fragmentary cross sectional elevation view, taken along an A-A′ line of FIG. 1, illustrating a memory cell in a step, subsequent to the step of FIGS. 10A and 10B, involved in the method of forming the semiconductor device of FIGS. 1, 2A and 2B;

FIG. 11B is a fragmentary cross sectional elevation view, taken along a B-B′ line of FIG. 1, illustrating a memory cell in a step, subsequent to the step of FIGS. 10A and 10B, involved in the method of forming the semiconductor device of FIGS. 1, 2A and 2B;

FIG. 12A is a fragmentary cross sectional elevation view, taken along an A-A′ line of FIG. 1, illustrating a memory cell in a step, subsequent to the step of FIGS. 11A and 11B, involved in the method of forming the semiconductor device of FIGS. 1, 2A and 2B;

FIG. 12B is a fragmentary cross sectional elevation view, taken along a B-B′ line of FIG. 1, illustrating a memory cell in a step, subsequent to the step of FIGS. 11A and 11B, involved in the method of forming the semiconductor device of FIGS. 1, 2A and 2B;

FIG. 13A is a fragmentary cross sectional elevation view, taken along an A-A′ line of FIG. 1, illustrating a memory cell in a step, subsequent to the step of FIGS. 12A and 12B, involved in the method of forming the semiconductor device of FIGS. 1, 2A and 2B;

FIG. 13B is a fragmentary cross sectional elevation view, taken along a B-B′ line of FIG. 1, illustrating a memory cell in a step, subsequent to the step of FIGS. 12A and 12B, involved in the method of forming the semiconductor device of FIGS. 1, 2A and 2B;

FIG. 14A is a fragmentary cross sectional elevation view, taken along an A-A′ line of FIG. 1, illustrating a memory cell in a step, subsequent to the step of FIGS. 13A and 13B, involved in the method of forming the semiconductor device of FIGS. 1, 2A and 2B;

FIG. 14B is a fragmentary cross sectional elevation view, taken along a B-B′ line of FIG. 1, illustrating a memory cell in a step, subsequent to the step of FIGS. 13A and 13B involved in the method of forming the semiconductor device of FIGS. 1, 2A and 2B;

FIG. 15A is a fragmentary cross sectional elevation view, illustrating a memory cell in a step, subsequent to the step of FIGS. 14A and 14B involved in the method of forming the semiconductor device of FIGS. 1, 2A and 2B;

FIG. 15B is a fragmentary cross sectional elevation view, illustrating a memory cell in a step, subsequent to the step of FIG. 15A involved in the method of forming the semiconductor device of FIGS. 1, 2A and 2B;

FIG. 16A is a fragmentary cross sectional elevation view, taken along an A-A′ line of FIG. 1, illustrating a memory cell in a step, subsequent to the step of FIGS. 14A and 14B involved in the method of forming the semiconductor device of FIGS. 1, 2A and 2B;

FIG. 16B is a fragmentary cross sectional elevation view, taken along a B-B′ line of FIG. 1, illustrating a memory cell in a step, subsequent to the step of FIGS. 14A and 14B involved in the method of forming the semiconductor device of FIGS. 1, 2A and 2B;

FIG. 17A is a fragmentary cross sectional elevation view, illustrating a memory cell in a step, subsequent to the step of FIGS. 15A and 15B, involved in the method of forming the semiconductor device of FIGS. 1, 2A and 2B;

FIG. 17B is a fragmentary cross sectional elevation view, illustrating a memory cell in a step, subsequent to the step of FIG. 17A, involved in the method of forming the semiconductor device of FIGS. 1, 2A and 2B;

FIG. 18A is a fragmentary cross sectional elevation view, a memory cell in a step, subsequent to the step of FIG. 17C, involved in the method of forming the semiconductor device of FIGS. 1, 2A and 2B;

FIG. 18B is a fragmentary cross sectional elevation view, illustrating a memory cell in a step, subsequent to the step of FIG. 117D, involved in the method of forming the semiconductor device of FIGS. 1, 2A and 2B;

FIG. 19A is a fragmentary cross sectional elevation view, illustrating a memory cell in a step, subsequent to the step of FIGS. 18A and 18B, involved in the method of forming the semiconductor device of FIGS. 1, 2A and 2B;

FIG. 19B is a fragmentary cross sectional elevation view, illustrating a memory cell in a step, subsequent to the step of FIGS. 18A and 18B, involved in the method of forming the semiconductor device of FIGS. 1, 2A and 2B;

FIG. 20A is a fragmentary cross sectional elevation view, taken along an A-A′ line of FIG. 1, illustrating a memory cell in a step, subsequent to the step of FIGS. 16A and 16B, involved in the method of forming the semiconductor device of FIGS. 1, 2A and 2B;

FIG. 20B is a fragmentary cross sectional elevation view, taken along a B-B′ line of FIG. 1, illustrating a memory cell in a step, subsequent to the step of FIGS. 16A and 16B, subsequent to the step of FIGS. 19A and 19B, involved in the method of forming the semiconductor device of FIGS. 1, 2A and 2B;

FIG. 21A is a fragmentary cross sectional elevation view, taken along an A-A′ line of FIG. 1, illustrating a memory cell in a step, subsequent to the step of FIGS. 20A and 20B, involved in the method of forming the semiconductor device of FIGS. 1, 2A and 2B;

FIG. 21B is a fragmentary cross sectional elevation view, taken along a B-B′ line of FIG. 1, illustrating a memory cell in a step, subsequent to the step of FIGS. 20A and 20B, involved in the method of forming the semiconductor device of FIGS. 1, 2A and 2B;

FIG. 22A is a fragmentary cross sectional elevation view, taken along an A-A′ line of FIG. 1, illustrating a memory cell in a step, subsequent to the step of FIGS. 21A and 21B, involved in the method of forming the semiconductor device of FIGS. 1, 2A and 2B;

FIG. 22B is a fragmentary cross sectional elevation view, taken along a B-B′ line of FIG. 1, illustrating a memory cell in a step, subsequent to the step of FIGS. 21A and 21B, involved in the method of forming the semiconductor device of FIGS. 1, 2A and 2B;

FIG. 23A is a fragmentary cross sectional elevation view, taken along an A-A′ line of FIG. 1, illustrating a memory cell in a step, subsequent to the step of FIGS. 22A and 22B, involved in the method of forming the semiconductor device of FIGS. 1, 2A and 2B;

FIG. 23B is a fragmentary cross sectional elevation view, taken along a B-B′ line of FIG. 1, illustrating a memory cell in a step, subsequent to the step of FIGS. 22A and 22B, involved in the method of forming the semiconductor device of FIGS. 1, 2A and 2B;

FIG. 24A is a fragmentary cross sectional elevation view, taken along an A-A′ line of FIG. 1, illustrating a memory cell in a step, subsequent to the step of FIGS. 23A and 23B, involved in the method of forming the semiconductor device of FIGS. 1, 2A and 2B;

FIG. 24B is a fragmentary cross sectional elevation view, taken along a B-B′ line of FIG. 1, illustrating a memory cell in a step, subsequent to the step of FIGS. 23A and 23B, involved in the method of forming the semiconductor device of FIGS. 1, 2A and 2B;

FIG. 25 a fragmentary plan view integrally illustrating a memory cell including a semiconductor device in accordance with one embodiment of the present invention;

FIG. 26A is a fragmentary cross sectional elevation view, taken along an A-A′ line of FIG. 1, illustrating a memory cell in a step, subsequent to the step of FIGS. 24A and 24B, involved in the method of forming the semiconductor device of FIGS. 1, 2A and 2B;

FIG. 26B is a fragmentary cross sectional elevation view, taken along a B-B′ line of FIG. 1, illustrating a memory cell in a step, subsequent to the step of FIGS. 24A and 24B, involved in the method of forming the semiconductor device of FIGS. 1, 2A and 2B;

FIG. 27A is a fragmentary cross sectional elevation view, taken along an A-A′ line of FIG. 1, illustrating a memory cell including a semiconductor device in accordance with another embodiment of the present invention;

FIG. 27B is a fragmentary cross sectional elevation view, taken along a B-B′ line of FIG. 1, illustrating a memory cell including a semiconductor device in accordance with another embodiment of the present invention;

FIG. 28A is a fragmentary cross sectional elevation view, taken along an A-A′ line of FIG. 1, illustrating a memory cell including a semiconductor device in accordance with another embodiment of the present invention;

FIG. 28B is a fragmentary cross sectional elevation view, taken along a B-B′ line of FIG. 1, illustrating a memory cell including a semiconductor device in accordance with another embodiment of the present invention;

FIG. 29 is a fragmentary cross sectional elevation view illustrating a memory cell including a semiconductor device in accordance with a related art of the present invention;

FIG. 30 is a fragmentary cross sectional elevation view illustrating a memory cell including a semiconductor device in accordance with a related art of the present invention;

FIG. 31 is a fragmentary cross sectional elevation view illustrating a memory cell including a semiconductor device in accordance with a related art of the present invention; and

FIG. 32 is a fragmentary cross sectional elevation view illustrating a memory cell including a semiconductor device in accordance with a related art of the present invention.

### DETAILED DESCRIPTION OF THE PREFERRED EMBODIMENTS

Before describing the present invention, the related art will be explained in detail, with reference to drawings, in order to facilitate the understanding of the present invention.

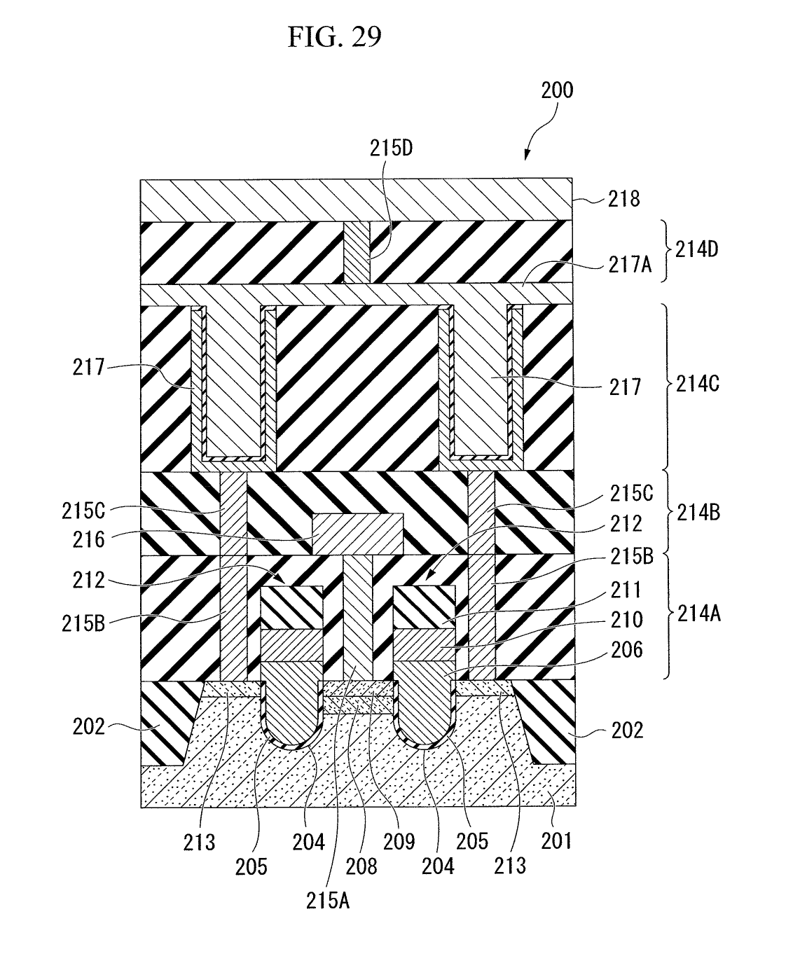

FIG. 29 is a schematic cross-sectional view showing an example of a structure of a DRAM including a trench-gate cell transistor. In a DRAM 200 having the structure shown in FIG. 29, element isolation regions 202 are formed in a surface of a P-type silicon substrate 201 and spaced apart from each other from side to side. Gate trenches 204 are formed in a region of the semiconductor substrate 201 interposed between the element isolation regions 202 and spaced apart from each other in a lateral direction of FIG. 33. Gate electrodes 212 are formed to fill the gate trenches 204 through a gate insulating film 205 formed on inner walls of the gate trenches 204 between the gate electrodes 212 and the gate trenches 204.

The gate electrodes 212 fill the gate trenches 204 and simultaneously protrude upward from the silicon substrate 201. In the above-described structure, each of the gate electrodes 212 has a triple structure obtained by sequentially stacking a polysilicon (poly-Si) film 206, a metal film 210 having a high-melting point, and a gate cap insulating film 211. Portions protruding from the gate trenches 204 are covered by a first interlayer insulating film 214A formed on the semiconductor substrate 201.

A high-concentration P-type diffusion layer 208 and a high-concentration N-type diffusion layer 209 are stacked on the surface of the silicon substrate 201 between the gate electrodes 212 shown in FIG. 29, while low-concentration N-type diffusion layers 213 are simultaneously formed in regions outside the gate electrodes 212. A contact plug 215A, which is a bit line contact, functioning as a vertical electrical conduction path is formed in the first interlayer insulating film 214A formed over the high-concentration N-type diffusion layer 209. Contact plugs 215B functioning as vertical electrical conduction paths are formed in the first interlayer insulating film 214A formed over the low-concentration N-type diffusion layers 213.

Next, a second interlayer insulating film 214B is formed over the first interlayer insulating film 214A. A bit line 216 is formed in the second interlayer insulating film 214B formed over the contact plug 215A, and second contact plugs 215C functioning as vertical electrical conduction paths are simultaneously formed in the second interlayer insulating film 214B formed over the contact plugs 215B.

Furthermore, a third interlayer insulating film 214C is formed over the second interlayer insulating film 214B. Cell capacitors 217 are formed in the third interlayer insulating film 214 formed on the second contact plugs 215C. A fourth interlayer insulating film 214D is formed over the third interlayer insulating film 214C. Upper electrodes 217A of the cell capacitors 217 are connected to an upper interconnection 218 via a third contact plug 215D formed in the fourth interlayer insulating film 214D. Thus, the DRAM 200 having the schematic structure shown in FIG. 33 is constructed.

In the structure of the DRAM 200 including the trench-gate cell transistor shown in FIG. 33, since the gate electrodes 212 are configured to protrude upward from the silicon substrate 201 to the first interlayer insulating film 214A, the contact plug 215A, which is a bit line contact, should be necessarily formed between gate lines connected to the gate electrodes 212. However, since the interval between the gate lines is extremely small, processing of the contact plug 215A is difficult.

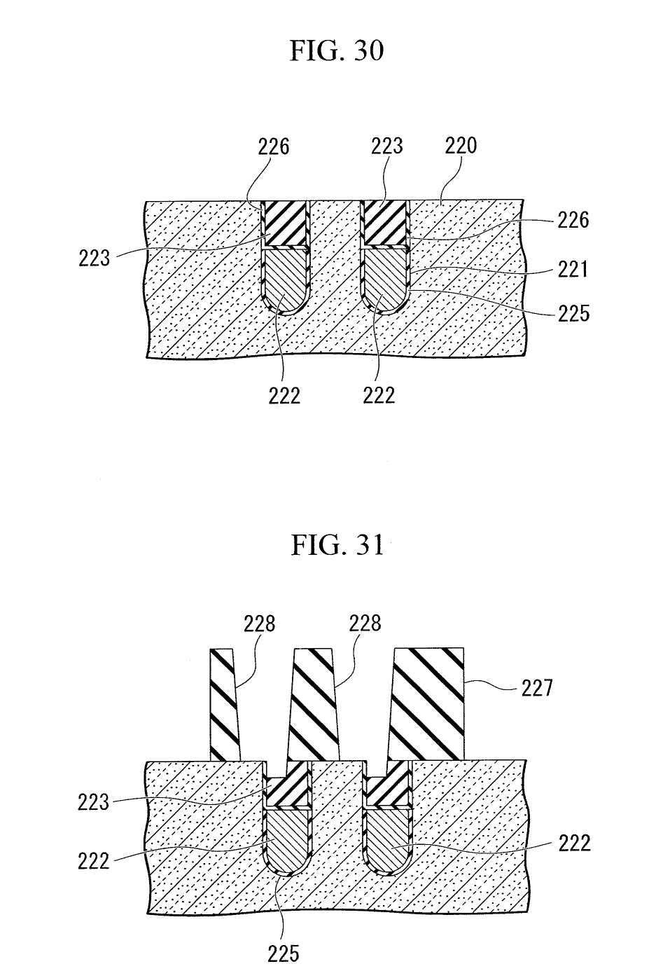

In the trench gate cell transistor, in order to avoid the problem, a structure may be employed in which the gate electrode 222 is embedded in the trench 221 formed in the silicon substrate 220 as shown in FIG. 30. An embedded insulating film 223 is formed in the trench 221 so as not to protrude from the trench 221. In the structure shown in FIG. 30, a gate insulating film 225 is formed around the gate electrode 222 on the lower inside of the trench 221. A liner film 226 is formed around the embedded insulating film 223 on the upper inside of the trench 221. In this state, an SOG (Spin On Glass) film with an excellent embedding property may be used as the embedded insulating film 223.

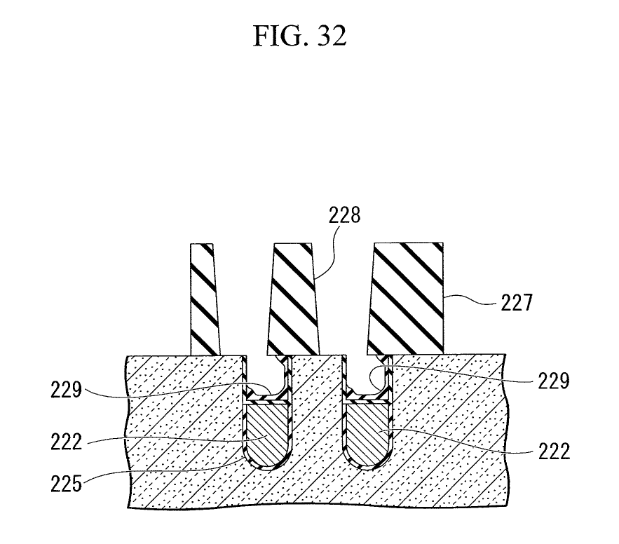

When employing the trench gate cell transistor structure shown in FIG. 30, in order to form the contact plug for connecting a conductive film thereunder and a conductive film thereover, the interlayer insulating film 227 is formed. A contact hole 228 is formed as shown in FIG. 31, and the contact plug is formed using the contact hole 228. However, by an etching process when the contact hole 228 is formed in the interlayer insulating film 227 and by a pre-cleaning process when the contact plug is formed, the embedded insulating film 223 of the SOG film positioned under the contact hole 228 may be partially etched greatly as shown in FIG. 32. Accordingly, a large etching hole 229 may be formed in the embedded insulating film 223. As a result, there is a concern that the gate electrode 222 and the contact plug formed later may be shorted.

The inventor had made a study of a material of the embedded insulating film 223. As a result, it was found that there was a problem with an embedding property and wet etching resistance occurring in an insulating film based on any of an HDP (High Density Plasma) method, a TEOS (Tetra Ethyl Ortho Silicate)-NSG (Non-doped Silicate Glass) film, and an SiO₂ film based on an atomic layer deposition (ALD) method.

Embodiments of the invention will be now described herein with reference to illustrative embodiments. Those skilled in the art will recognize that many alternative embodiments can be accomplished using the teaching of the embodiments of the present invention and that the invention is not limited to the embodiments illustrated for explanatory purpose.

In one embodiment, a method of forming a semiconductor device may include, but is not limited to the following processes. A groove is formed in a semiconductor substrate. A gate electrode is formed in the groove. A boron-phosphorus silicate glass film is formed over the gate electrode. An etching process is performed using the boron-phosphorus silicate glass film as an etching stopper for preventing the gate electrode from being removed.

In some cases, a method of forming the semiconductor device may include, but is not limited to, heating the boron-phosphorus silicate glass film.

In some cases, heating the boron-phosphorus silicate glass film may include, but is not limited to, heating the boron-phosphorus silicate glass film in a water vapor atmosphere.

In some cases, the method may further include, but is not limited to, forming a first layered structure over the boron-phosphorus silicate glass film and the semiconductor substrate. Performing the etching process may includes patterning the first layered structure.

In some cases, forming the first layered structure may include, but is not limited to, forming a metal film of a first metal.

In some cases, the method may include, but is not limited to, the gate electrode including the first metal.

In some cases, the method may include, but is not limited to, forming the first layered structure includes forming a nitride film.

In some cases, the method may further include, but is not limited to, forming a liner film comprising nitride over the gate electrode before forming the boron-phosphorus silicate glass film.

In some cases, the method may further include, but is not limited to the following processes. A second layered structure is formed over the semiconductor substrate. An opening is formed in the second layered structure to expose a first portion of the semiconductor substrate. A cleaning process is performed to clean the first portion using the boron-phosphorus silicate glass film as an etching stopper for protecting the gate electrode.

In some cases, the method may further include, but is not limited to, planarizing a surface of the boron-phosphorus silicate glass film.

In some cases, planarizing the surface of the boron-phosphorus silicate glass film may include, but is not limited to, heating the boron-phosphorus silicate glass film.

In some cases, the method may include, but is not limited to, the boron-phosphorus silicate glass film having a concentration in the range of boron from 10.5 mol % to 11.0 mol % and the boron-phosphorus silicate glass film having a concentration in the range of phosphorus from 2.34 mol % to 2.76 mol %.

In some cases, forming the method may include, but is not limited to, may include, but is not limited to, the boron-phosphorus silicate glass film having a sum of concentrations of boron and phosphorus, which is in the range from 14.3 mol % to 15.7 mol %.

In some cases, forming the boron-phosphorus silicate glass film may include, but is not limited to, performing a CVD process.

In another embodiment, a method of forming a semiconductor device may include, but is not limited to the following processes. A boron-phosphorus silicate glass film is formed over a semiconductor substrate. A multi-layered structure comprising an oxide film is formed over the boron-phosphorus silicate glass film and the semiconductor substrate. An opening in the oxide film is formed to expose a first portion of the semiconductor substrate and a second portion of the boron-phosphorus silicate glass film. A cleaning process is performed to clean the first portion in a condition where the boron-phosphorus silicate glass film is lower in etching rate than the oxide film.

In some cases, the method may further include, but is not limited to the following processes. A groove is formed in the semiconductor substrate. A gate electrode is formed in the groove before forming the boron-phosphorus silicate glass film over the gate electrode.

In some cases, the performing the cleaning process may include, but is not limited to, the cleaning process using the boron-phosphorus silicate glass film as a stopper for protecting the gate electrode.

In some cases, the method may further include, but is not limited to, forming a contact plug in the opening, the contact plug contacting the first portion.

In some cases, the method may further include, but is not limited to, heating the boron-phosphorus silicate glass film before forming the multi-layered structure. The heating the boron-phosphorus silicate glass film may include heating the boron-phosphorus silicate glass film in a water vapor atmosphere.

In still another embodiment, a method of forming a semiconductor device may include, but is not limited to the following processes. A groove is formed in the semiconductor substrate. A gate electrode is formed in the groove. An insulating film is formed in the groove and over the semiconductor substrate. A boron-phosphorus silicate glass film is formed in the groove and over the semiconductor substrate. A surface of the boron-phosphorus silicate glass film and a surface of the semiconductor substrate are planarized.

In still another embodiment, a semiconductor device may include, but is not limited to, a semiconductor substrate having a groove, a gate electrode in the groove, and an insulating film comprising a boron-phosphorus silicate glass. The insulating film extends over the gate electrode. The insulating film is in the groove. The insulating film has a top surface substantially the same in level as a top surface of the semiconductor substrate.

In some cases, the semiconductor device may include, but is not limited to, the boron-phosphorus silicate glass film having a concentration in the range of boron from 10.5 mol % to 11.0 mol %. The boron-phosphorus silicate glass film has a concentration in the range of phosphorus from 2.34 mol % to 2.76 mol %.

In some cases, the semiconductor device may include, but is not limited to, the boron-phosphorus silicate glass film having a sum of concentrations of boron and phosphorus, which is equal or less than 14.3 mol %.

In some cases, the semiconductor device may further include, but is not limited to, a liner layer between the gate electrode and the insulating layer.

In some cases, the semiconductor device may include, the liner layer comprises silicon nitride.

In some cases, the semiconductor device may include, the thickness of the liner layer is equal to or more than 10 nm.

Hereinafter, in one embodiment, a DRAM (Dynamic Random Access Memory) as the semiconductor device will be described. In the drawings used for the following description, to facilitate understanding of the embodiments, illustrations are partially enlarged and shown, and the sizes and ratios of constituent elements are not limited to being the same as the actual dimensions. Materials, sizes, and the like exemplified in the following description are just examples, and the invention is not limited thereto and may be appropriately modified within the scope which does not deviate from the embodiments.

<Structure of Semiconductor Memory Device>

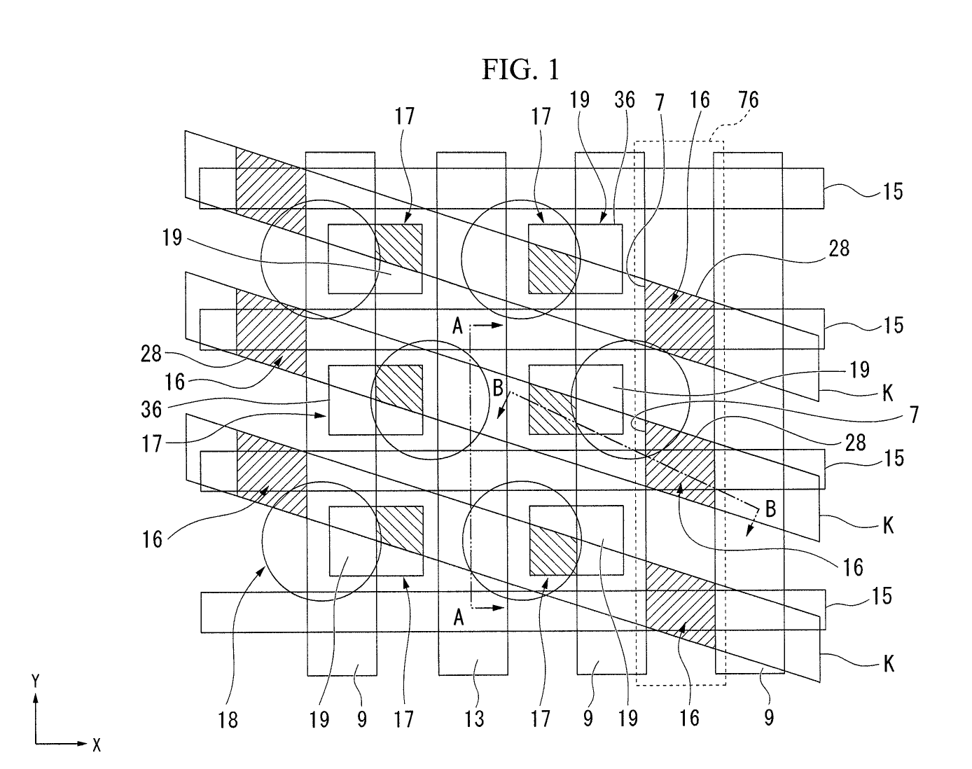

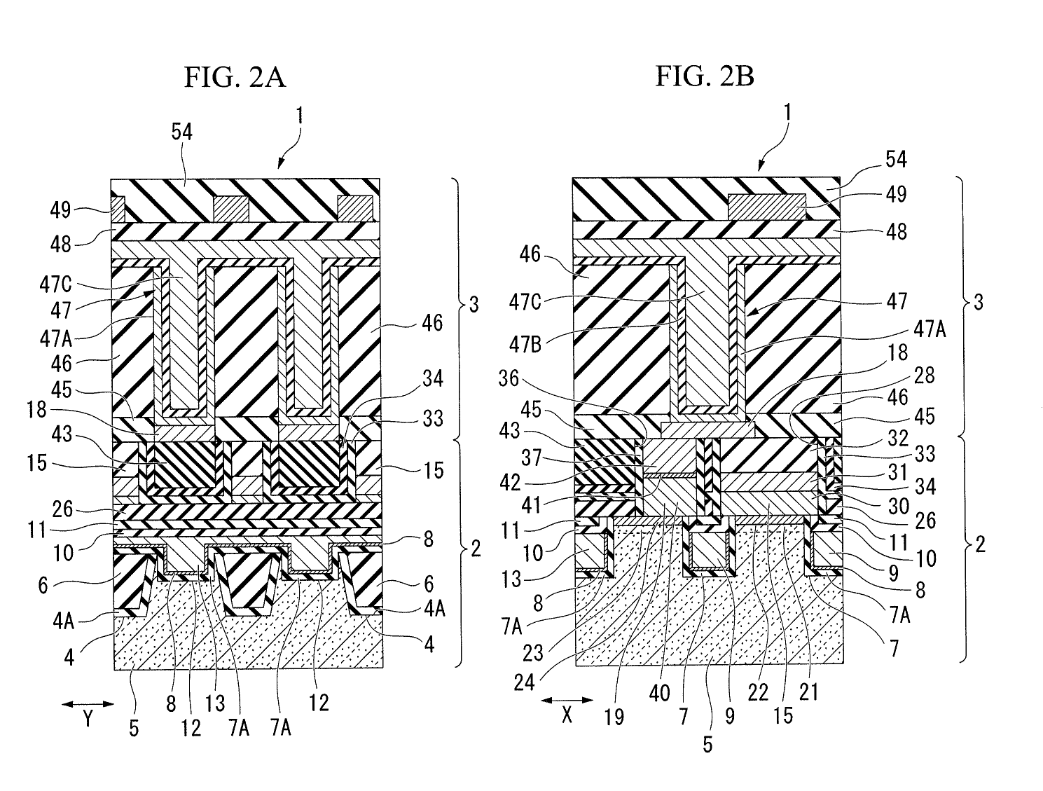

FIG. 1 is a plan view of some elements of a cell structure of a semiconductor memory device. FIGS. 2A and 2B are partial cross-sectional views of the semiconductor memory device. FIG. 2A is a cross-sectional view taken along line A-A′ of FIG. 1, and FIG. 2B is a cross-sectional view taken along line B-B′ of FIG. 1.

A semiconductor memory device 1 of an embodiment of the present invention has a cell-transistor forming region 2 and a cell-capacitor forming region 3 shown in the cross-sectional views of FIGS. 2A and 2B. A semiconductor substrate 5 may be a conductive silicon substrate.

In the transistor forming region 2, a plurality of strip-shaped active regions K are formed in one surface of the semiconductor substrate 5 in a direction inclined at a predetermined angle with respect to an X direction of FIG. 1 and spaced by a predetermined distance apart from one another in a Y direction. In addition, to define the active regions K, a plurality of element isolation trenches 4 having a sectional shape shown in FIG. 2A are formed in a direction inclined at a predetermined angle with the X direction of FIG. 1. The plurality of element isolation trenches 4 are spaced by a predetermined distance apart from one another in the Y direction of FIGS. 1 and 2A. As shown in FIG. 2A, an inner insulating film 4A may include a silicon oxide film on inner surfaces of the element isolation trenches 4. An element isolation insulating film 6 may include a silicon nitride film inside the inner insulating film 4A to fill the element isolation trenches 4, thereby forming element isolation regions (shallow trench isolation (STI) regions).

Also, as shown in FIG. 2B, a plurality of gate-electrode trenches 7 extend in the Y direction of FIG. 1 and are spaced a predetermined distance apart from each other in the X direction of FIGS. 1 and 2B. A gate insulating film 7A may include a silicon oxide film on inner surfaces of the gate-electrode trenches 7. A buried word line 9 may include a metal having a high melting point, such as tungsten (W), inside the gate insulating film 7A with an inner surface film 8 which may include titanium nitride interposed therebetween. A buried insulating film 11 is formed over the buried word line 9 to fill the gate-electrode trenches 7 with a liner film 10 interposed therebetween. In FIG. 1, the gate-electrode trenches 7 in which the buried word lines 9 are formed include two kinds of trenches. One of trenches is formed as a channel of a trench-gate transistor in a portion overlapping the active region K. The other of trenches is formed as a trench formed in the STI region adjacent to the active region K to a smaller depth than the trench formed in the active region K. The buried word line 9 is formed as a single continuous interconnection with a planar top surface to fill two kinds of trenches with different depths.

Furthermore, in the one embodiment of the present invention, the gate insulating film 7A and the liner film 10 are formed such that top end edges of the gate insulating film 7A and the liner film 10 reach openings of the gate-electrode trenches 7. The buried insulating film 11 is formed to fill a convex portion of the liner film 10 formed in an opening of the gate insulating film 7A. Thus, the buried insulating film 11, the gate insulating film 7A, and the liner film 10 are stacked such that a top surface of the buried insulating film 1, a top end edge of the gate insulating film 7A, and a top end edge of the liner film 10 substantially form one plane.

In the embodiment, the embedded insulating film 11 is formed of boron-phosphorus silicate glass (BPSG: boron-phosphorus silicate glass including boron (B) and phosphorus (P)). As the boron-phosphorus silicate glass used herein, a BPSG film is employed in which a concentration of boron (B) is in the range of 10.5 mol % to 11.0 mol % and a ratio of concentration of boron (B) and phosphorus (P) is in the range of 2.34 to 2.76. The embedded insulating film 11 will be described in detail in a description of a method of manufacturing a semiconductor device to be described later. In the liner film 10, it is necessary that the thickness of a film be equal to or more than 10 nm, and a silicon nitride film such as Si₃N₄ is appropriate as a material thereof.

As shown in FIG. 2A, a channel trench 12 is formed to a smaller depth than the element isolation trench 4 in a region between the element isolation trenches 4 adjacent to each other in the Y direction. The gate insulating film 7A may include a silicon oxide film over inner surfaces of the channel trench 12 and top surface of the element isolation trench 4 disposed adjacent to the channel trench 12. An element isolation buried wiring 13 is formed over the gate insulating film 7A with the inner surface film 8 which may include titanium nitride interposed therebetween. The liner film 10 and the buried insulating film 11 are stacked on the buried wiring 13. The liner film 10 and the buried insulating film 11 shown in FIG. 2A are the same as the liner film 10 and the buried insulating film 11 formed over the buried word line 9 shown in FIG. 2B, which are fabricated during by the following method.

Also, the element isolation buried wiring 13 is formed while the buried word line 9 is formed. The element isolation buried wiring 13 functions to electrically isolate source and drain regions, that is, impurity diffusion regions formed on both sides of the element isolation buried line 13 shown in FIG. 1, which constitute respective adjacent transistors in an active region formed in a line shape. Conventionally, an active region is formed as an isolated pattern surrounded by a buried element isolation region formed using an insulating film. Accordingly, source and drain regions cannot be formed in a desired shape in an end portion of the active region due to the resolution limit of a lithography process. However, the construction of the one embodiment of the present invention may avoid the above-described problem because an active region may be formed in a line-shaped pattern.

As shown in FIGS. 1 and 2B, a plurality of buried word lines 9 extend in the Y direction and are spaced apart from one another in the X direction. However, in the structure of the one embodiment of the present invention, as shown in FIG. 2B, two buried word lines 9 and one element isolation buried wiring 13 are alternately arranged in this order in the X direction.

Also, as shown in FIG. 1, a bit line 15, which will be described in detail later, is disposed in a direction perpendicular to a direction in which the buried word line 9 and the buried line 13 are arranged. Accordingly, the active regions K having a strip-type plane shape are formed in the surface of the semiconductor substrate 5 to be inclined at a predetermined angle with a direction in which each of the buried word wirings 9 and each of the bit lines 15 extend. Since the active regions K are formed in the surface of the semiconductor substrate 5, a bit line connection region 16 is defined in a portion of the active region K disposed below each of the bit lines 15. Also, when an interconnection structure is viewed from the plan view as shown in FIG. 1, a capacitor contact plug forming region 17 is defined in a portion where the active region K exists, in a region between the buried word line 9 and the element isolation buried wiring 13 adjacent to the buried word line 9 in the X direction and between the bit lines 15 and 15 adjacent to another bit line in the Y direction.

Accordingly, when the interconnection structures is viewed from the plan view, as shown in FIG. 1, the bit lines 15 are approximately orthogonal to the buried word line 9 and the element isolation buried line 13. Simultaneously, the strip-shaped active regions K are disposed at an angle with the bit lines 15. Bit line connection regions 16 are formed in portions of the active regions K corresponding to regions between adjacent buried word lines 9. The capacitor contact plug forming region 17 is defined in a region between the buried word line 9 and the element isolation region 13 and between adjacent bit lines 15. Also, a capacitor contact pad 18 that will be described later is formed in a zigzag pattern with respect to the capacitor contact plug forming region 17 in the Y direction of FIG. 1. Although the capacitor contact pads 18 are disposed in the X direction of FIG. 1 between the bit lines 15 adjacent to each other in the Y direction, the capacitor contact pads 18 are repetitively disposed zigzag in several positions in the Y direction. For example, the center of one capacitor contact pad 18 may be disposed over the buried word line 9 in the Y direction and the center of another capacitor contact pad 18 may be disposed over one side of the buried word line 9. In other words, the capacitor contact pads 18 are disposed zigzag in the Y direction.

Next, in the one embodiment of the present invention, the capacitor contact plug 19 formed in the capacitor contact plug forming region 17 is formed in a rectangular shape as shown in FIG. 1. However, a portion of the capacitor contact plug 19 is disposed on each of the buried word lines 9, while the remaining portion of the capacitor contact plug 19 is disposed to be located in a region between the adjacent bit lines 15 and over a region between the buried word line 9 and the element isolation buried line 13 so that each of the capacitor contact plugs 19 can be connected to a capacitor 47 that will be described later.

From the plan view of FIG. 1, the capacitor contact plug forming region 17 may cover a portion of the buried word line 9, a portion of the STI region, and a portion of the active region K. Accordingly, from the plan view, the capacitor contact plug 19 is formed to range over the portion of the buried word line 9, the portion of the STI region, and the portion of the active region K.

The transistor forming region 2 will be described again with reference to FIGS. 2A and 2B. As shown in FIG. 2B, a low-concentration impurity diffusion layer 21 and a high-concentration impurity diffusion layer 22 are formed sequentially from a depth direction on the surface of the semiconductor substrate 5 located between the buried word lines 9 adjacent to each other in the X direction and in a region corresponding to the active region K. A low-concentration impurity diffusion layer 23 and a high-concentration impurity diffusion layer 24 are formed sequentially from the depth direction on the surface of the semiconductor substrate 5 located between the buried word line 9 and the element isolation buried wiring 13 adjacent in the X direction and in a region corresponding to the active region K.

Thus, a first interlayer insulating film 26 is formed to cover the buried insulating film 11 in the region shown in FIG. 2A. The first interlayer insulating film 26 is formed over the semiconductor substrate 5 in the region shown in FIG. 2B. That is, the first interlayer insulating film 26 is formed to cover the cover the high-concentration impurity diffusion layers 22 and 24 and the gate-electrode trench 7 in which the buried word line 9, the liner film 10, and the buried insulating film 11 are formed.

A contact hole 28 is formed in a region of the first interlayer insulating film 26 between the gate-electrode trenches 7 adjacent to each other in the X direction of FIG. 2B. As shown in FIG. 1, the bit lines 15 are formed over the first interlayer insulating film 26 and extend in a direction perpendicular to the buried word line 9. In this case, the bit lines 15 are disposed in portion of the contact hole 28, extend to lower portion of the contact hole 28. Further, the bit lines 15 are connected to the high-concentration impurity layer 22 formed under the respective contact holes 28. Accordingly, a portion including the bit line 15 of a region in which the contact hole 28 is formed, i.e., a region having the high-concentration impurity diffusion layer 22 therebeneath becomes the bit line connection region 16.

The bit line 15 has a triple structure including a lower conductive film 30 which may include polysilicon, a metal film 31 which may include a metal having a high melting point, such as tungsten (W), and an upper insulating film 32 which may include silicon nitride. An insulating film 33, such as a silicon nitride film, and a liner film 34 are respectively formed on both sides of a widthwise direction of the bit line 15 shown in FIG. 2B and on the first interlayer insulating film 26 shown in FIG. 2A.

A capacitor contact opening 36, which has a rectangular shape when viewed from a plan view, is formed in a region between the bit lines 15 adjacent to each other in the Y direction of FIG. 1. The capacitor contact opening 36 is over a region between an upper region of the buried word line 9 and the element isolation buried wiring 13 disposed adjacent thereto. A capacitor contact plug 19 is formed within the capacitor contact opening 36 and surrounded by sidewalls 37 which may include a silicon nitride film. Accordingly, a portion where the capacitor contact opening 36 is formed corresponds to the capacitor contact plug forming region 17. As shown in FIG. 2B, the capacitor contact plug 19 has a triple layer structure including a lower conductive film 40 which may include polysilicon, a silicide film 41 which may include CoSi, and a metal film 42 which may include W. Also, the bit line 15 and the capacitor contact plug 19 are formed on the semiconductor substrate 5 at the same level. Also, a buried insulating film 43 is formed in the remaining region of the bit line 15 and the capacitor contact plug 19 at the same level as the bit line 15 and the capacitor contact plug 19.

Next, in the capacitor forming region 3 shown in FIGS. 2A and 2B, each of the capacitor contact pads 18 having a circular shape shown in FIG. 1 is formed to be zigzag with respect to the capacitor contact plug 19 to partially overlap the capacitor contact plug 19 from a plan view. Each of the capacitor contact pads 18 is covered by a stopper film 45, while a third interlayer insulating film 46 is simultaneously formed over the stopper 45. A capacitor 47 is formed over each of the capacitor contact pads 18 within the third interlayer insulating film 46.

The capacitor 47 according to the one embodiment of the present invention includes a cup-type lower electrode 47A, a capacitor insulating film 47B, an upper electrode 47C, a fourth interlayer insulating film 48, an upper metal interconnection 49, and a protection film 54. The cup-type lower electrode 47A is formed over the capacitor contact pad 18. The capacitor insulating film 47B is formed to extend from the inside of the lower electrode 47A to the third interlayer insulating film 46. The upper electrode 47C is formed to bury the inside of the lower electrode 47A within the capacitor insulating film 47B and simultaneously extend to the top surface of the capacitor insulating film 47B. The fourth interlayer insulating film 48 is formed over the upper electrode 47. The upper metal interconnection 49 is formed over the fourth interlayer insulating film 48. The protection film 54 is formed to cover the upper metal interconnection 49 and the fourth interlayer insulating film 48. In addition, the structure of the capacitor 47 formed in the capacitor forming region 3 is an example, and other typical capacitors (e.g., crown capacitors) applied to semiconductor memory devices may naturally be employed.

In the semiconductor memory device 1 of the embodiment, the embedded insulating film 11 is formed of the boron-phosphorus silicate glass (BPSG). Accordingly, when the capacitance contact opening 36 is formed, by etching, in the interlayer insulating film 26 formed over the embedded insulating film 11, there is an effect that the embedded insulating film 11 is not etched more than required during etching. Furthermore, it is possible to avoid making a short circuit between the embedded word lines 9 and the capacitance contact plug 19 formed thereover.

A process and an operational effect at the etching time will be described in detail in a method of manufacturing a semiconductor memory device to be described hereinafter.

<Method of Fabricating Semiconductor Device>

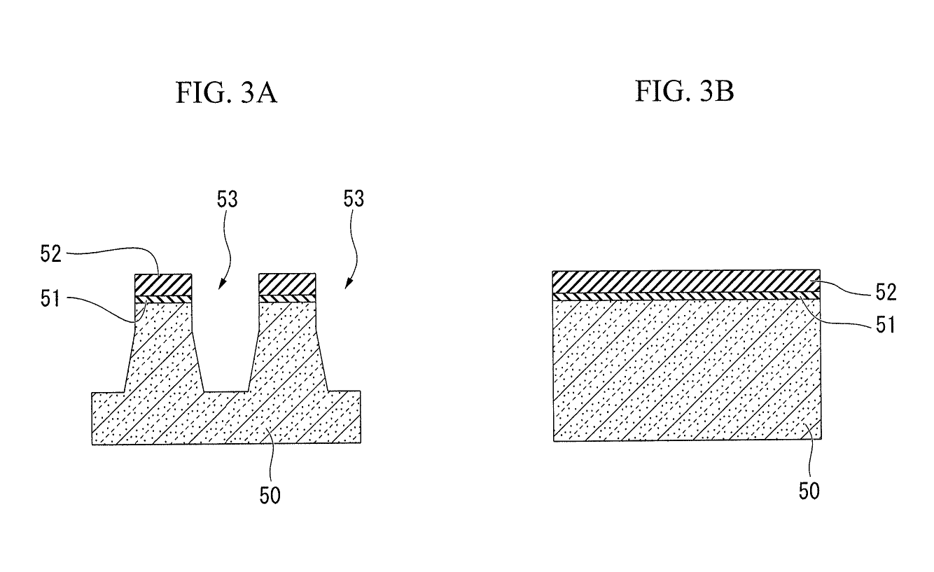

Next, an example of a method of fabricating the semiconductor device shown in FIGS. 1, 2A, and 2B will be described with reference to FIGS. 3A through 23B. FIGS. 3A through 23A are cross-sectional views of portions taken along line A-A′ of FIG. 1, and FIGS. 3B through 23B are cross-sectional views of portions taken along line B-B′ of FIG. 1.

A semiconductor substrate 50, such as a P-type Si substrate, is prepared as shown in FIGS. 3A and 3B. A silicon oxide film 51 and a silicon nitride (Si₃N₄) film 54 serving as a mask are sequentially stacked. Also, a semiconductor substrate in which a P-well is previously formed using an ion implantation process in a region where a transistor is to be formed may be used as the semiconductor substrate 50.

Next, the silicon oxide film 51, the silicon nitride film 52, and the semiconductor substrate 50 are patterned using photolithography and dry etching techniques, thereby forming element isolation trench 53. The element isolation trench is formed in a surface of the silicon substrate 50 to define active regions K. From the plan view of the semiconductor substrate 50, the element isolation trench 53 is formed as a line-shaped pattern trench extending in a predetermined direction between both sides of the strip-shaped active region K of FIG. 1. A region corresponding to the active region K is covered by the silicon nitride film 52.

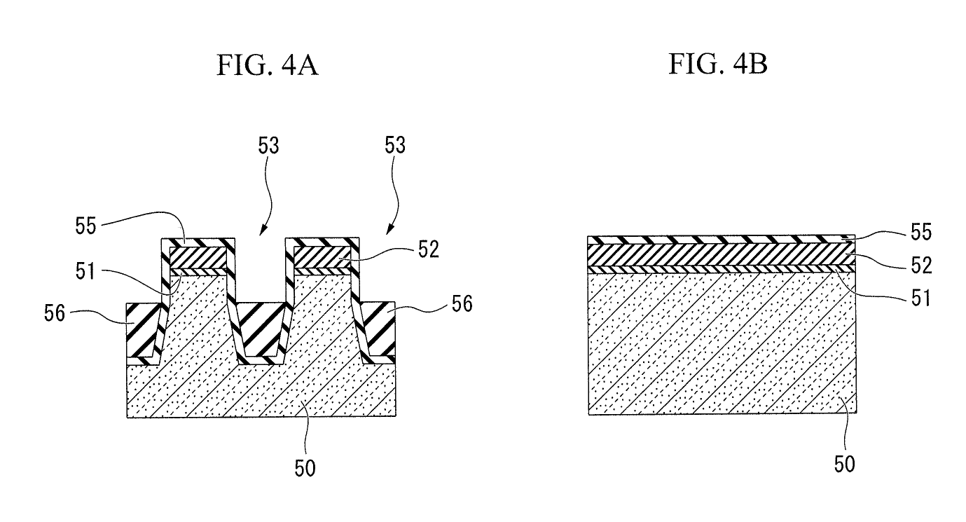

Next, as shown in FIGS. 4A and 4B, a silicon oxide film 55 is formed using a thermal oxidation method on the surface of the semiconductor substrate 50. Afterwards, a silicon nitride film is deposited to fill the element isolation trench 53 and then etched back. Thus, the silicon nitride film is left only in a lower portion of the element isolation trench 53 and filled up to a slightly lower position than the top surface of the semiconductor substrate 50. An element isolation insulating film 56 having such a thickness is completed as shown in FIGS. 4A and 4B.

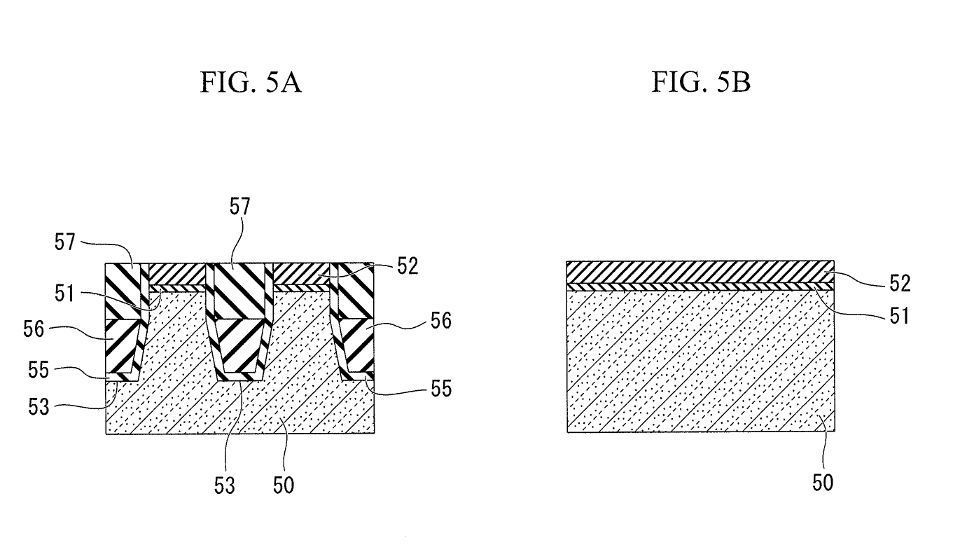

Next, a silicon oxide film 57 is deposited using a CVD process to fill the inside of the element isolation trench 53. The surface of the silicon oxide film 57 is planarized using a chemical mechanical polishing (CMP) process as shown in FIGS. 5A and 5B until the silicon nitride film 52 serving as a mask, which is formed in FIG. 3, is exposed.

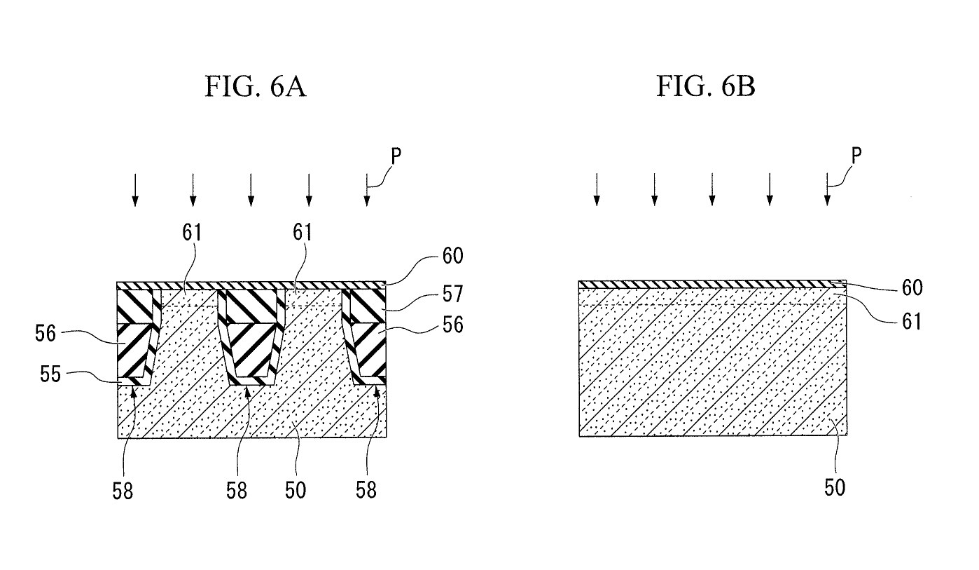

Next, the silicon nitride film 52 serving as the mask and the silicon oxide film 51 are removed using a wet etching process so that the surface of the element isolation trench 53 is substantially the same level as the surface of the silicon substrate 50. Thus, a line-shaped element isolation region 58 using an STI structure shown in FIGS. 6A and 6B is formed. After the surface of the silicon substrate 50 is exposed, a thermal oxidation process is carried out, thereby forming a silicon oxide film 60 in the surface of the semiconductor substrate 50.

Subsequently, as shown in FIGS. 6A and 6B, low-concentration N-type impurity ion, such as phosphorus ion, are introduced, thereby forming an N-type low-concentration impurity diffusion layer 61. The N-type low-concentration impurity diffusion layer 61 functions as a portion of source and drain (S/D) regions of a recess-type transistor according to the present invention.

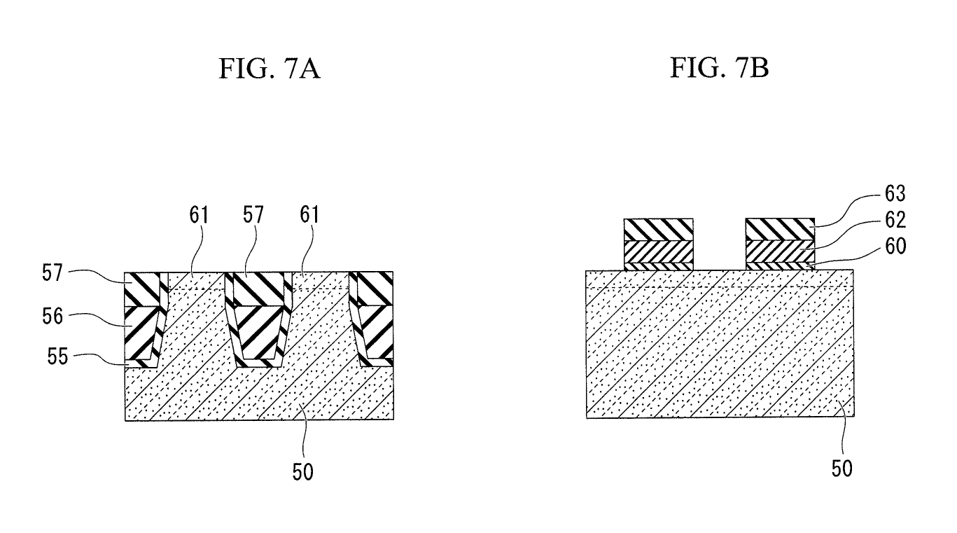

Next, a silicon nitride film 62 serving as a mask and a carbon film 63, which is an amorphous carbon film, are sequentially deposited and patterned to form a gate-electrode trench, which is a trench, as shown in FIGS. 7A and 7B.

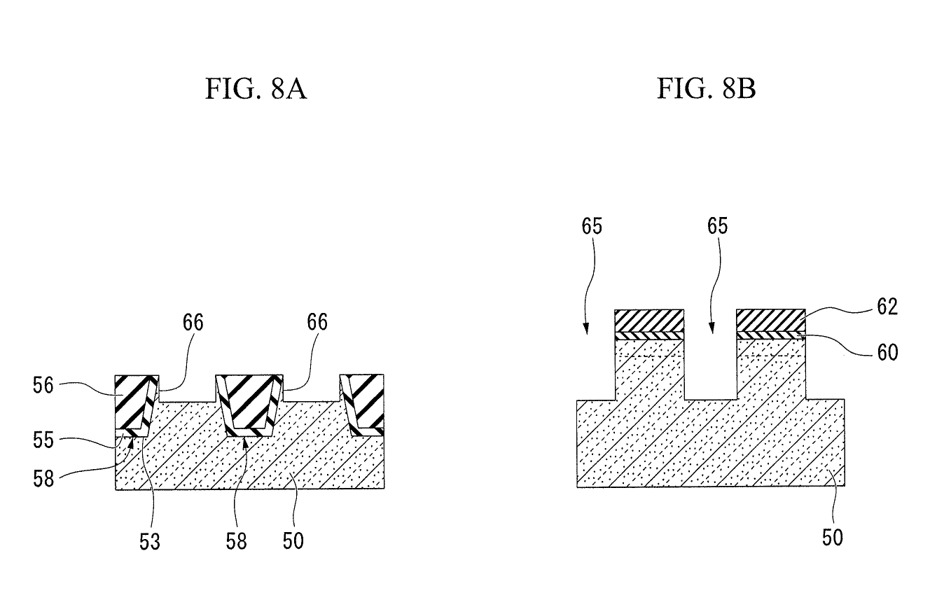

Also, as shown in FIGS. 8A and 8B, the semiconductor substrate 50 is etched using a dry etching process, thereby forming trenches 65, which is a gate-electrode trench. The trench 65 is formed in line-shaped patterns extending in a predetermined direction, which is the Y direction of FIG. 1, to intersect the active region K.

At this time, a top surface of the element isolation region 58 disposed within the trench 65 is also etched, thereby forming a shallow trench in a lower position than the top surface of the semiconductor substrate 50. Etching conditions are controlled such that a silicon oxide film is etched at a lower etch rate than the semiconductor substrate 50. Thus, the trench 65 is formed as a continuous trench having a lower portion with a step difference. That is, the trench 65 is the continuous trench including a deep trench formed by etching the semiconductor substrate 50 and a shallow trench formed by etching the element isolation region 58. As a result, as shown in FIGS. 8A and 8B, a thin silicon film is remained as sidewalls 66 in a lateral surface of the trench 65 neighboring the element isolation region 58 and functions as a channel region of a recess-type cell transistor. By etching silicon of the semiconductor 50 to a greater depth than the element isolation region (STI) 58, a channel region of a recess channel transistor is formed as shown in FIGS. 8A and 8B.

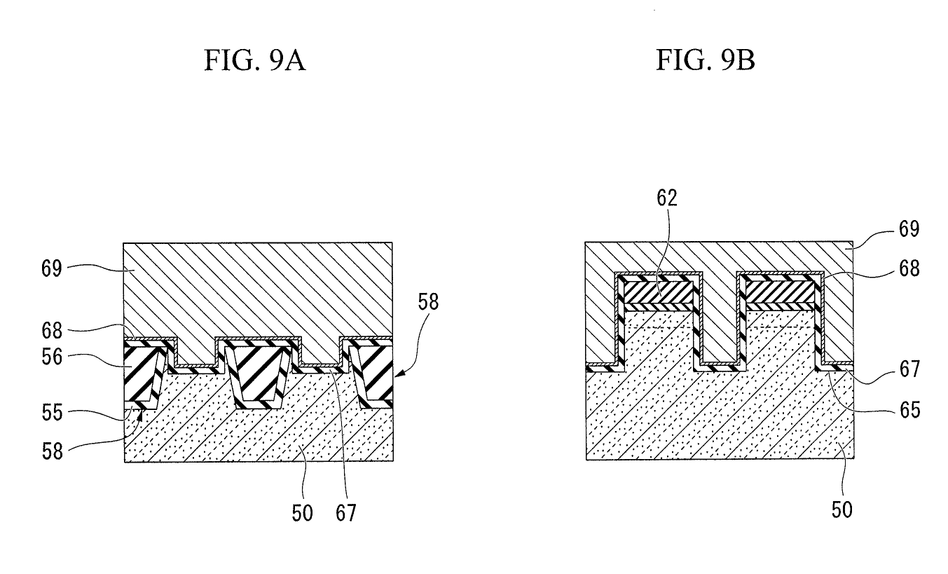

Next, a gate insulating film 67 is formed as shown in FIGS. 9A and 9B. A silicon oxide film formed using a thermal oxidation process may be used as the gate insulating film 67. Afterwards, an inner surface film 68 which may include titanium nitride (TiN) and tungsten (W) film 69 are sequentially deposited.

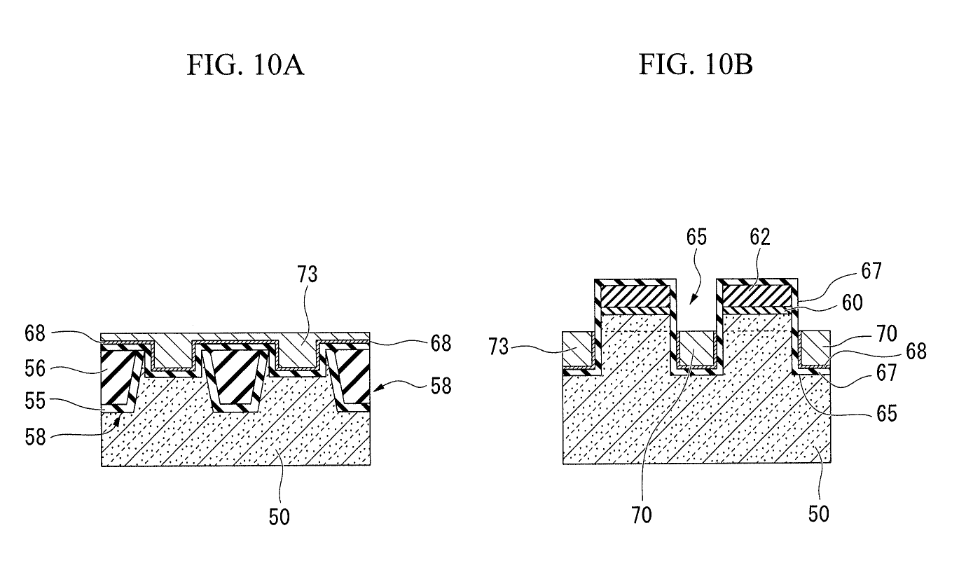

Next, an etch-back process is performed until the inner surface film 68 and the tungsten film 69 are left in a lower portion of the trench 65. Thus, as shown in FIGS. 10A and 10B, a buried word line 70, which constitutes a portion of a gate electrode, and an element isolation buried wiring 73 are formed.

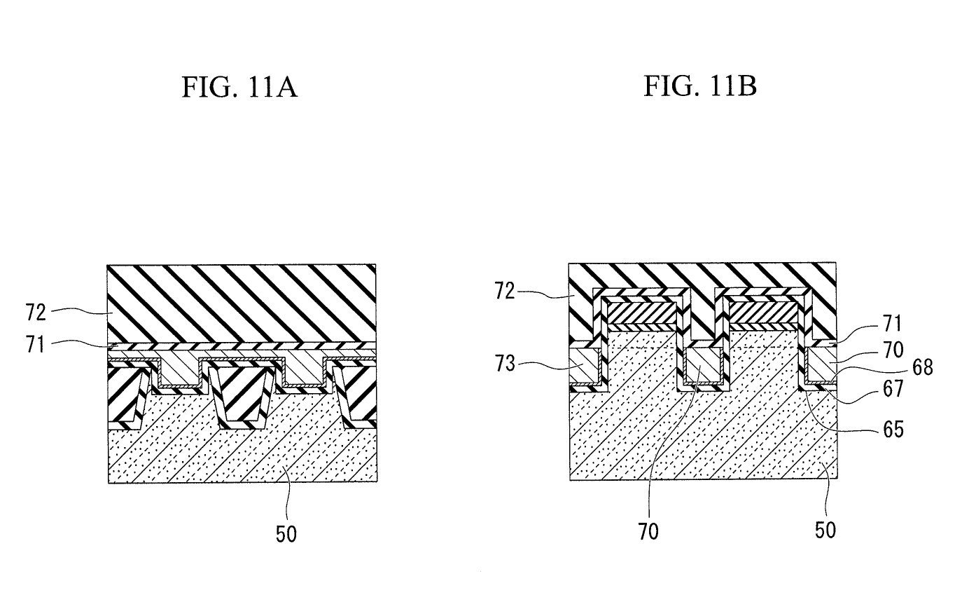

As shown in FIG. 11A and FIG. 11B, a liner film 71 is formed of a silicon nitride film (Si₃N₄) or the like, to cover the upside of the remaining tungsten film 69 and the trench grooves 65. It is necessary that a thickness of the liner film 71 is about 10 nm. An embedded insulating film 72 is laminated over the liner film 71 by a CVD method.

In the embodiment, as the embedded insulating film 72, a boron-phosphorous silicate glass (BPSG: Boron-Phosphorus SiO₂ Glass) may be applied.

As the boron-phosphorous silicate glass used herein, a BPSG film may be selected in which a boron (B) concentration is in the range of 10.5 mol % to 11.0 mol %, and a ratio of the boron (B) concentration and a phosphorous (P) concentration is in the range of 2.34 to 2.76. When the boron concentration is 10.5 mol %, the phosphorous concentration corresponds to 3.8 mol % to 4.5 mol %. When the boron concentration is 11.0 mol %, the phosphorous concentration corresponds to 4.0 mol % to 4.7 mol %. The corresponding phosphorous is slightly changed according to the boron concentration. In the concentration condition within this range, the BPSG film can be sufficiently embedded on the upside of the gate electrode grooves 65. Quality of the BPSG film is governed by a sum of the boron concentration and the phosphorous concentration. When the sum is equal to or less than 14.3 mol %, there is no planarization effect based on glass flow, or when the sum is equal to or more than 15.7 mol %, there is a problem that there is a defect in that a hygroscopic property of the film becomes intensive, and an excessive component of boron or phosphorous is precipitated.

For the embedding, after the embedded insulating film 72 is formed, a heat treatment is performed at about 800° C. for about 10 minutes. The embedded insulating film 72 is made into glass flow (fluidization), the groove inside is filled, and the surface is planarized. The BPSG film is densified by the heat treatment, and etching resistance is improved. The BPSG film is a mixed film of B₂O₃, P₂O₅, and SiO₂, and the B concentration or the P concentration represents mol % as B₂O₃ or P₂O₅. The BPSG film can be formed by a CVD method using an inorganic material such as silane, diborane, and phosphine, or a CVD method using an organic material such as tetraethoxysilane, trimethylborate, and trimethylphosphate. Whatever method is used to form the BPSG film, a heat treatment for glass flow is necessary. It is preferable to perform a heat treatment in a water vapor atmosphere to reduce load of the heat treatment.

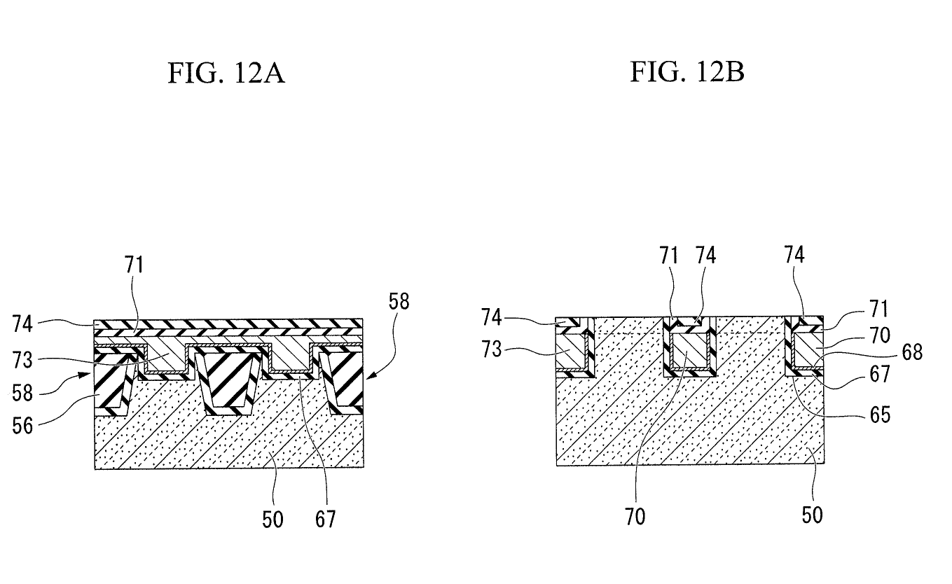

Next, as shown in FIGS. 12A and 12B, the surface of the buried insulating film 72 is planarized using a CMP process until the liner film 71 is exposed. Thereafter, the silicon nitride film serving as a mask and portions of the buried insulating film 72 and the liner film 71 are removed using an etching process so that the surface of the buried insulating film 72 can be substantially the same level as the silicon surface of the semiconductor substrate 50. Thus, a buried word line 70 and an element isolation buried wiring 73 are formed, and a buried insulating film 74 is formed over the buried word line 70 and the buried line 73.

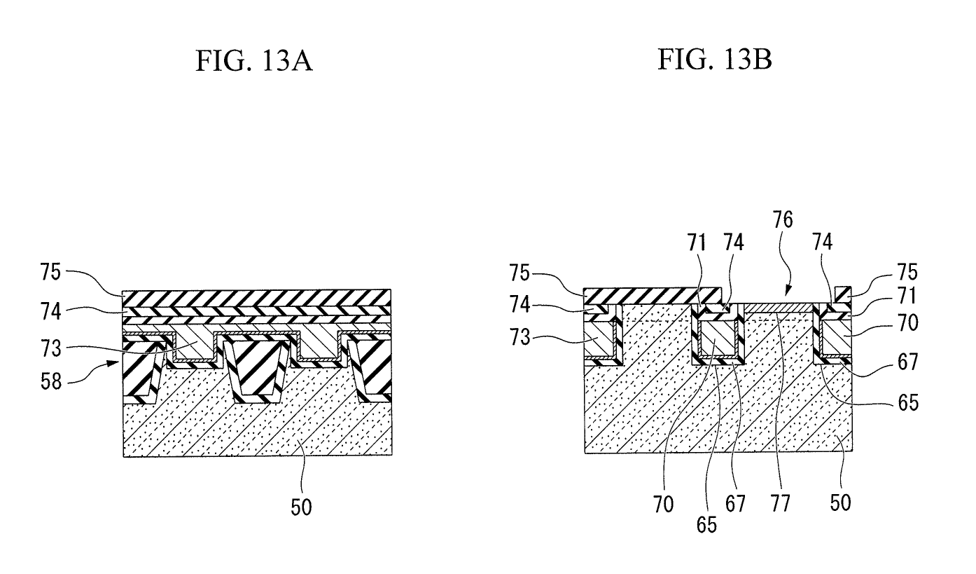

Next, as shown in FIGS. 13A and 13B, a first interlayer insulating film 75 may include a silicon oxide film to cover the semiconductor substrate 50. Afterwards, a portion of the first interlayer insulating film 75 is removed using photolithography and dry etching techniques, thereby forming a bit contact opening 76. As in the case shown in FIG. 1, the bit contact opening 76 is formed in a line-shaped opening pattern extending in the same direction as the buried word line 70 (the Y direction of FIG. 1 or a direction in which the buried word line 70 and the buried line 73 extend in FIGS. 13A and 13B). Hence, the Si surface of the semiconductor substrate 50 is exposed in a portion of the pattern of the bit contact opening 76, which intersects the active region K. Thus, the exposed portion is used as a bit line connection region.

After the bit contact opening 76 is formed, N-type impurity ion, such as arsenic (As) ion, is introduced, thereby forming a high-concentration N-type impurity diffusion layer 77 near the silicon surface of the semiconductor substrate 50. The high-concentration N-type impurity diffusion layer 77 functions as source and drain regions of a recess-type cell transistor.

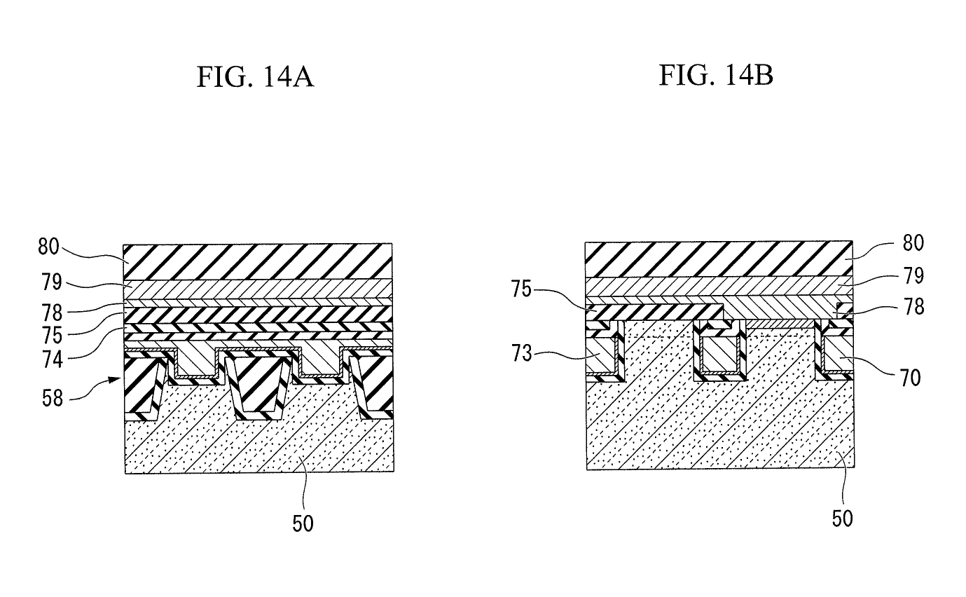

Then, as shown in FIGS. 14A and 14B, a lower conductive film 78 of a polysilicon film containing N type impurities (phosphorous, etc.), a metal film 79 such as a tungsten film, and a silicon nitride film 80 are sequentially laminated over the semiconductor substrate 50.

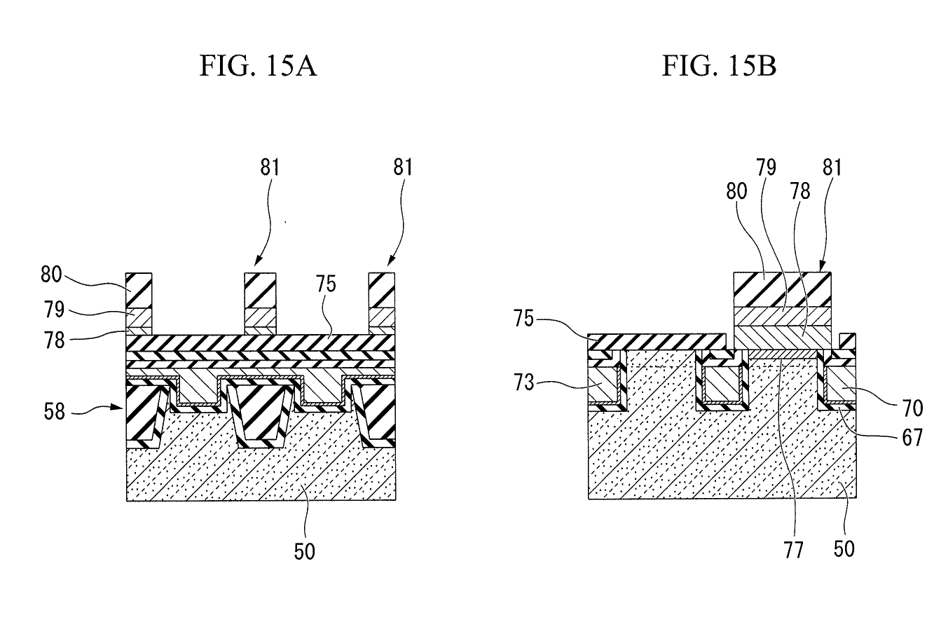

Then, as shown in FIG. 15A and FIG. 15B, the laminated film of the lower conductive film 78, the metal film 79, and the silicon nitride film 80 is patterned in a line shape, thereby forming bit lines 81. The bit lines 81 are formed in a pattern extending in a direction (X direction when the structure is described in FIG. 1) intersecting with the embedded word lines 70. As the structure shown in FIG. 1, the bit lines 81 are linearly shaped to be perpendicular to the embedded word lines 70, but the bit lines 81 may be disposed in a partially curved line shape or a wave shape. The lower conductive film 78 of the lower layer of the bit lines 81 and the N type impurity high-concentration diffusion layer 77 (a part of the source and drain areas) of the semiconductor substrate 50 are connected at the surface of the semiconductor substrate 50 formed of silicon exposed in the bit contact opening 76.

The embedded insulating film 74 is formed of the boron-phosphorous silicate glass (BPSG) over the gate electrode with the liner film 71 interposed therebetween. When the bit lines 81 are formed by patterning, the BPSG is used as an etching stopper. Since an etching rate of the BPSG is lower than that of the SOG which conventionally used for a material for the embedded insulating film, wet resistance is improved. It is possible to form the bit lines 95 to be described later without greatly etching the embedded insulating film 74.

Then, a silicon nitride film 82 covering the side face of the bit lines 81 is formed, and a liner film 83 covering the upper face is formed of a silicon nitride film or the like. The laminated film for the bit lines 81 can also serve as a gate electrode of a planar type MOS transistor in a peripheral circuit portion of the semiconductor memory device. The silicon nitride film 82 covering the side face of the bit lines 81 can be used as a part of the side wall of the gate electrode in the peripheral circuit portion.

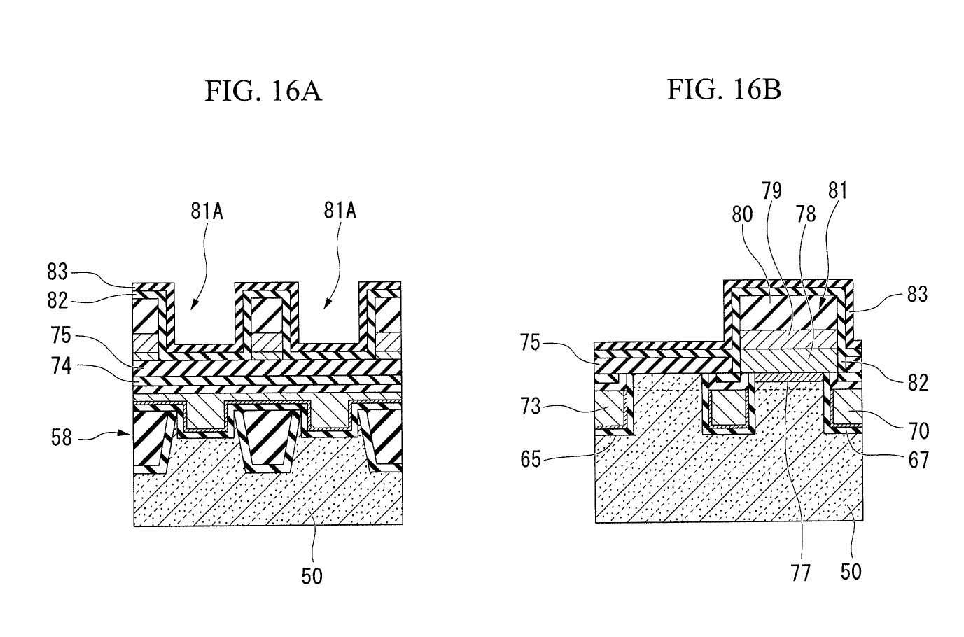

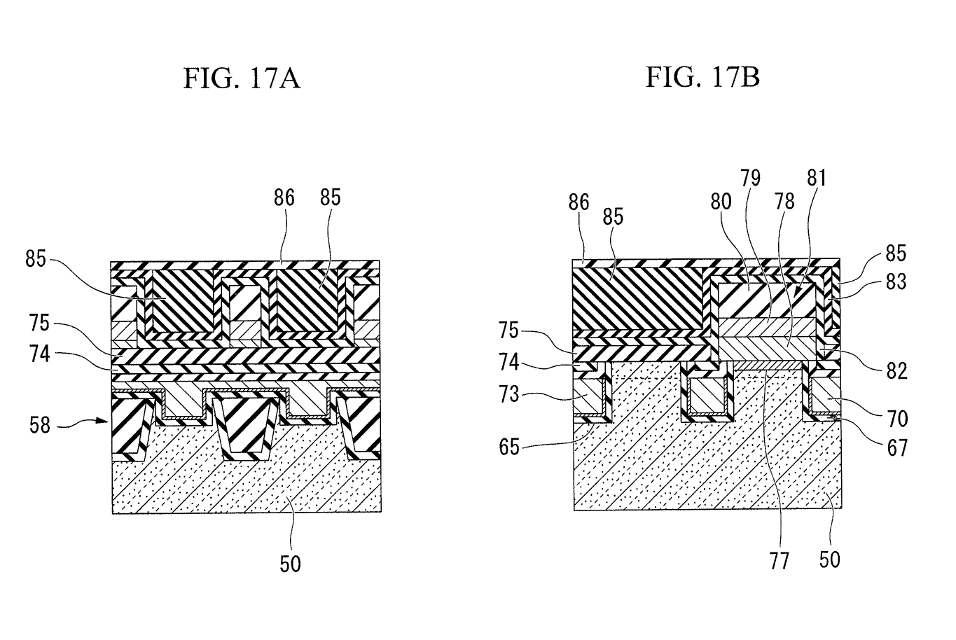

Then, an SOD film (Spin On Dielectrics: a coating insulating film such as polysilazane) that is a coating film is laminated as shown in FIG. 17A and FIG. 17B to fill a space portion 81A between the bit lines 81 and 81 shown in FIG. 16A and FIG. 16B. Thereafter, an anneal process is performed in the atmosphere of high temperature water vapor (H₂O), and it is reformed to a solid laminated film 85. The CMP process is performed for planarization until the upper face of the liner film 83 is exposed. Then, a silicon oxide film formed by a CVD method is formed as a second interlayer insulating film 86 to cover the surface of the laminated film 85.

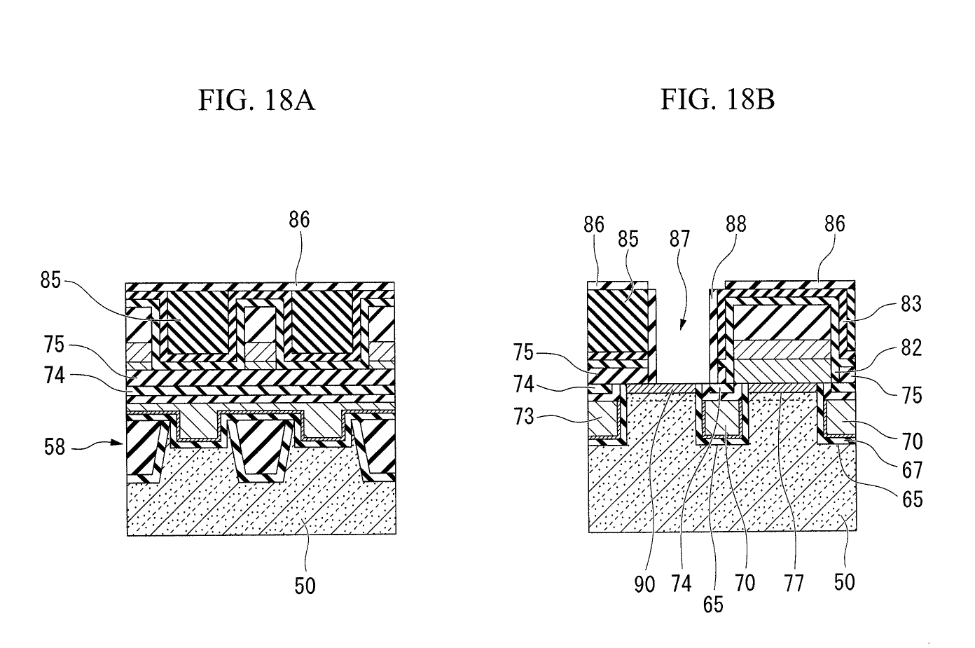

Next, as shown in FIGS. 18A and 18B, a capacitor contact opening 87 is formed using photolithography and dry etching techniques. In the case of the structure described above with reference to FIG. 1, the capacitor contact opening 87 is formed in a position corresponding to the capacitor contact plug forming region 17. Here, a self-aligned contact (SAC) process may be performed using the silicon nitride film 82 and the liner film 83 formed on lateral surfaces of the bit lines 81 as sidewalls, thereby forming the capacitor contact opening 87.

After forming the capacitance contact opening 87 by the dry etching, when the capacitance contact opening 87 and the periphery thereof are cleaned by a buffered hydrofluoric acid (Buffered HF: HF, NH₄F, and H₂O are mixed) before forming a contact plug 95 to be described later, the embedded insulating film 74 exists under the capacitance contact opening 87. The embedded insulating film 74 is formed of the boron-phosphorous silicate glass (BPSG). The BPSG is used in the cleaning process as an etching stopper. Since an etching rate of the BPSG is lower than that of the SOG, wet resistance is improved. It is possible to form the contact plug 95 to be described later without greatly etching the embedded insulating film 74.

The surface of the semiconductor substrate 50 is exposed at the intersecting part of the capacitance contact opening 87 and the active areas K. The embedded insulating film 74 is positioned under the exposed part, which is positioned over the embedded word lines 70 filling the trench grooves 65. However, since the embedded insulating film 74 is formed of the boron-phosphorous silicate glass (BPSG), the embedded insulating film 74 is not etched at the etching time to form an etching hole. Accordingly, there is no concern that the embedded word lines 70 under the embedded insulating film 74 may be short-circuited with the capacitance contact plug to be formed later. In this point, when the SOG film is used, the etching hole is formed as described in the related art. Accordingly, there is great concern that the embedded word lines 70 and the capacitance contact plug may be short-circuited.

According to the study of the inventor, even when any film of an insulating film based on an HDP (High Density Plasma) method, a TEOS (Tetra Ethyl Ortho Silicate)-NSG (Non-doped Silicate Glass) film, and an SiO₂ film based on an atomic layer deposition (ALD) method is applied as a material constituting the embedded insulating film 74, an embedding property is poor or there is a problem in wet etching resistance. For this reason, it is preferable that the embedded insulating film 74 is formed of boron-phosphorous silicate glass (BPSG).

As the boron-phosphorous silicate glass, a BPSG film may be selected in which a boron (B) concentration is in the range of 10.5 mol % to 11.0 mol %, and a ratio of the boron (B) concentration and a phosphorous (P) concentration is in the range of 2.34 to 2.76.

When the film includes B and P in the mol % ratio in this range, the boron-phosphorous silicate glass can be sufficiently embedded on the upside of the trench grooves 65, and etching resistance is excellent. When the ratio gets out of the range, for example, describing the embedding property, the embedding property is insufficient at the concentration ratio of 3.17. When the concentration ratio is 2.76, the wet etching rate is 11 nm/minute. When the concentration ratio is 2.34, the wet etching rate is 14 nm/minute. Since a range other than this range is outside of the permissible range of this process, the range is not preferable. In regard to this, a wet etching rate of the same chemical (buffered hydrofluoric acid) of SOG is 28 nm/minute, and a problem easily occurs in etching resistance at the wet etching rate.

Next, as shown in FIGS. 18A and 18B, sidewalls 88 may include a silicon nitride film to cover inner walls of the capacitor contact openings 87. After forming the sidewalls 88, N-type impurity ion, such as phosphorus ion, is introduced into the surface of the semiconductor substrate 50, thereby forming a high-concentration N-type impurity diffusion layer 90 near the surface of the semiconductor substrate 50. The resultant high-concentration N-type impurity diffusion layer 90 functions as a source or drain region of a recess-type transistor according to the one embodiment of the present invention.

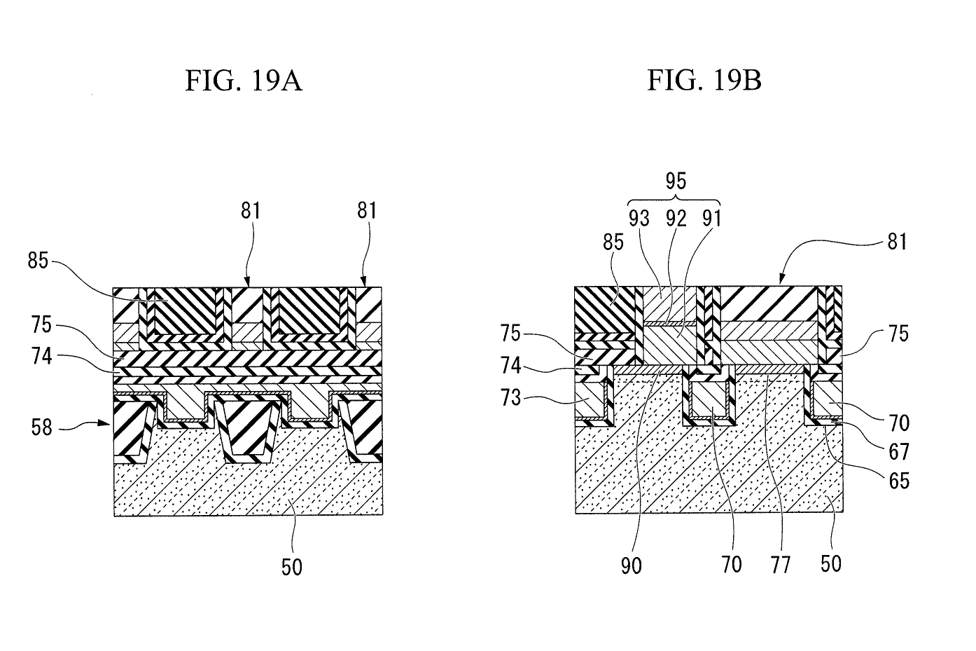

Next, as shown in FIGS. 19A and 19B, a P-containing polysilicon film is deposited and then etched back to leave the polysilicon film in a lower portion of the capacitor contact opening 87, thereby forming a lower conductive film 91. Afterwards, a silicide film 92 may include cobalt silicide (CoSi) on the surface of the lower conductive film 91. A metal film 93, such as a tungsten film, is deposited to fill the capacitor contact opening 87. The resultant structure is planarized using a CMP process until the surface of the deposition film 85 is exposed, so that the metal film 93, such as the tungsten film, can be remained only within the capacitor contact opening 87. Thus, a capacitor contact plug 95 with a triple layer structure may be formed.

Also, in the structure of the one embodiment of the present invention, as shown in FIGS. 19A and 19B, the capacitor contact plug 95 is formed over the high-concentration impurity diffusion layer 90 disposed between adjacent buried word lines 70 The bit line 81 is formed over the high-concentration impurity diffusion layer 77. Thus, the capacitor contact plug 95 and the bit line 81 are finely disposed over the buried word line 70 of the trench structure, thereby contributing to miniaturization.

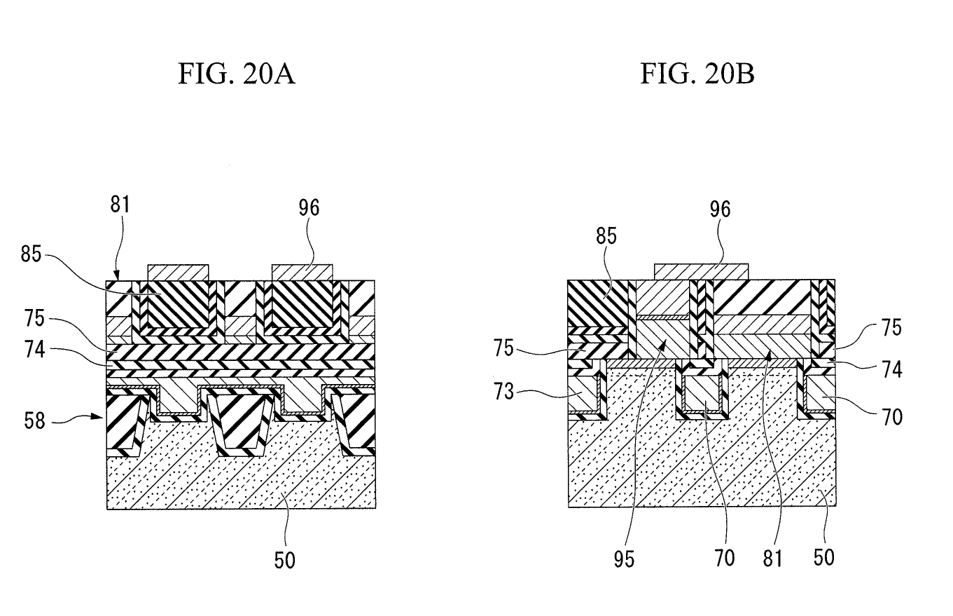

Next, a tungsten nitride (WN) film and a tungsten film are sequentially deposited and patterned, thereby forming a capacitor contact pad 96 shown in FIGS. 20A and 20B. The capacitor contact pad 96 is connected to the capacitor contact plug 95.

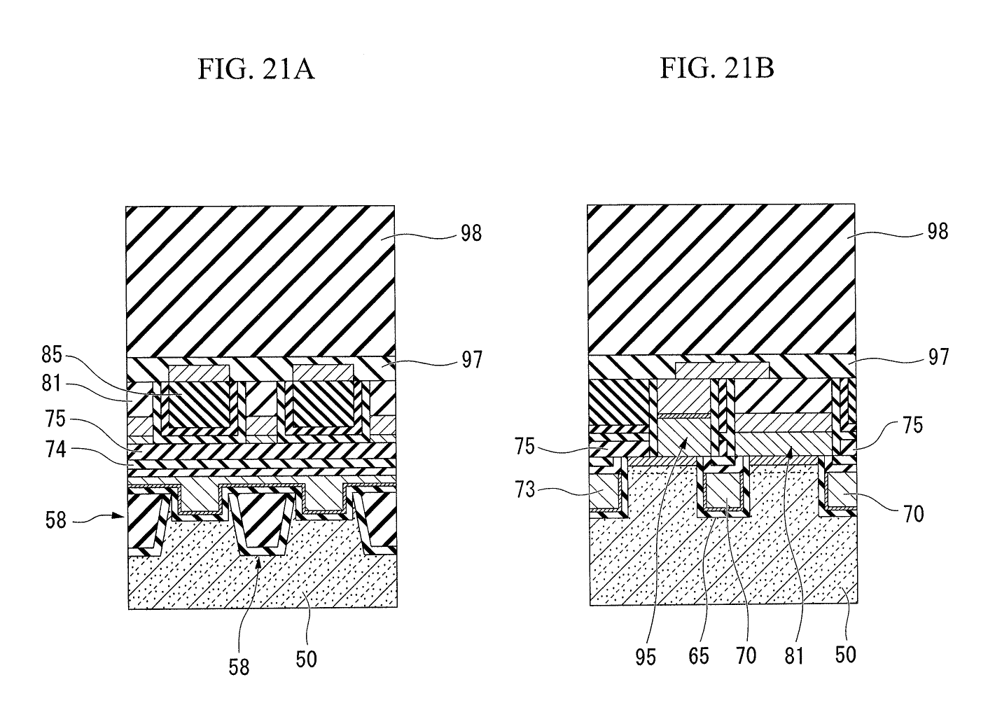

Next, as shown in FIGS. 21A and 21B, after a stopper film 97 may include a silicon nitride film to cover the capacitor contact pad 96, a third interlayer insulating film 97 may include a silicon oxide film.

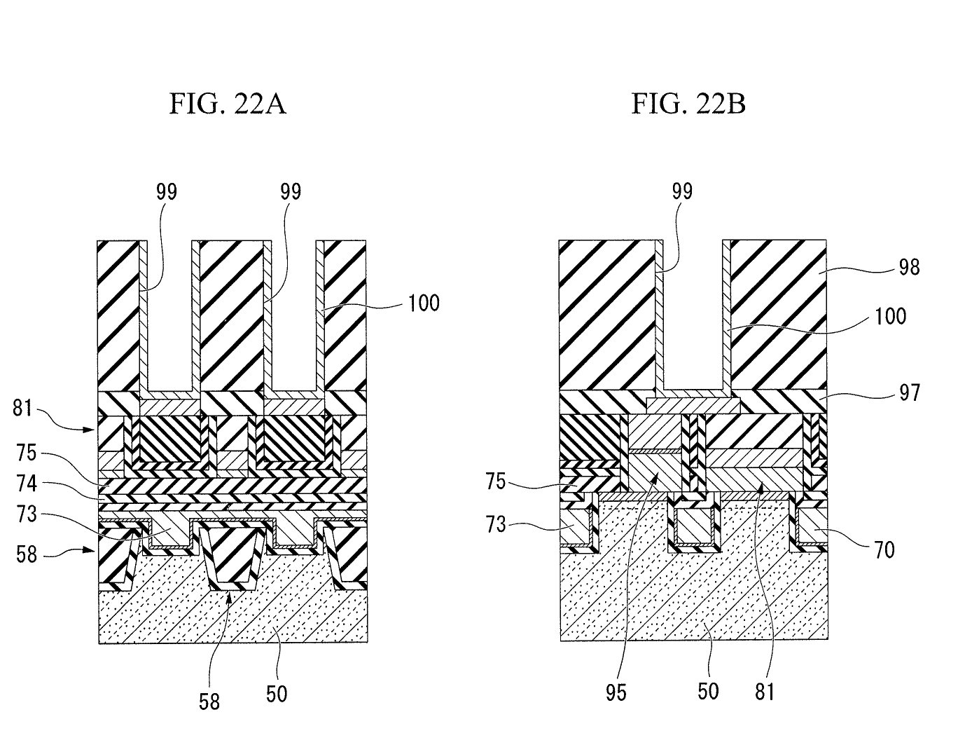

Thereafter, as shown in FIGS. 22A and 22B, an opening 99, which is a contact hole, is formed through the third interlayer insulating film 98 and the stopper film 97 to expose the top surface of the capacitor contact pad 96. Afterwards, a lower electrode 100 of a capacitor may include titanium nitride to cover an inner wall of the opening 99. A lower portion of the lower electrode 100 is connected to the capacitor contact pad 96.

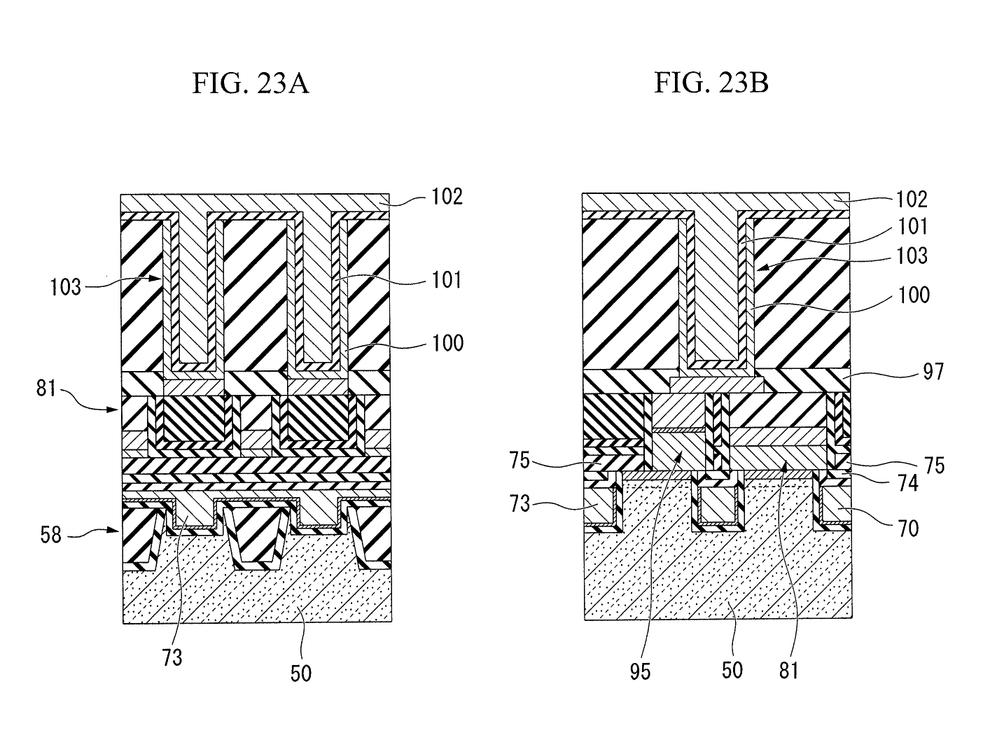

Next, as shown in FIGS. 23A and 23B, after a capacitor insulating film 101 is formed to cover the surface of the lower electrode 100, an upper electrode 102 of the capacitor may include titanium nitride. Thus, a capacitor 103 may be formed. The capacitor insulating film 101 may include zirconium oxide (ZrO₂), aluminum oxide (Al₂O₃), hafnium oxide (HfO₂), or a stacked layer thereof.

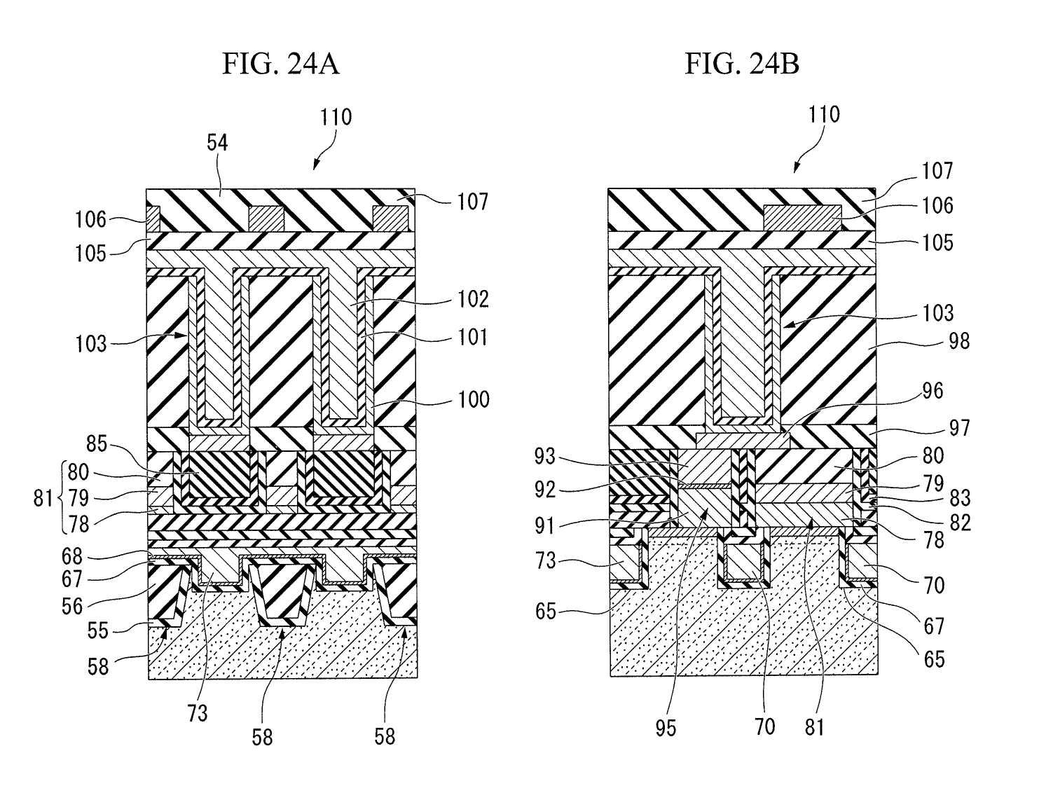

Next, as shown in FIGS. 24A and 24B, after a fourth interlayer insulating film 105 may include a silicon oxide film to cover the surface of the upper electrode 102, an upper metal interconnection 106 may include aluminum (Al) or copper (Cu). Afterwards, a surface protection film 107 is formed. As a result, as shown in FIGS. 24A and 24B, a semiconductor memory device 110 having the same structure as the semiconductor memory device 1, which is a DRAM, shown in FIGS. 1, 2A, and 2B is completed.

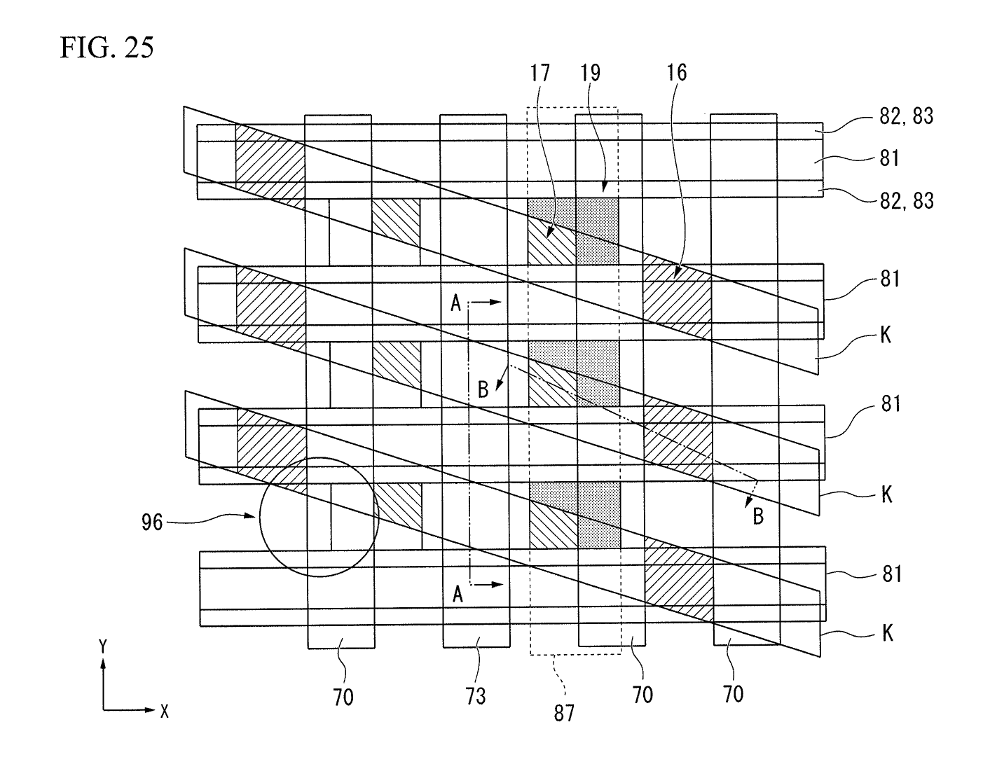

In addition, FIG. 25 shows a planar structure of a partial interconnection structure of the semiconductor memory device 110 obtained according to the above-described fabrication method.

The interconnection structure of FIG. 25 shows the insulating film 82 and the liner film 83 disposed on both sides of the bit lines, which are omitted from the interconnection structure of FIG. 1. FIG. 25 clearly shows the capacitor contact plug forming region 17 defined between the bit lines 81 adjacent to each other in the Y direction.

In view of the capacitor contact plug forming region shown in FIG. 25, it can be clearly understood that the capacitor contact opening 87 described above with reference to FIGS. 18A and 18B is precisely formed by an SAC technique using the liner film 83 as sidewalls. The capacitor contact plug 95 is formed using the capacitor contact opening 87.

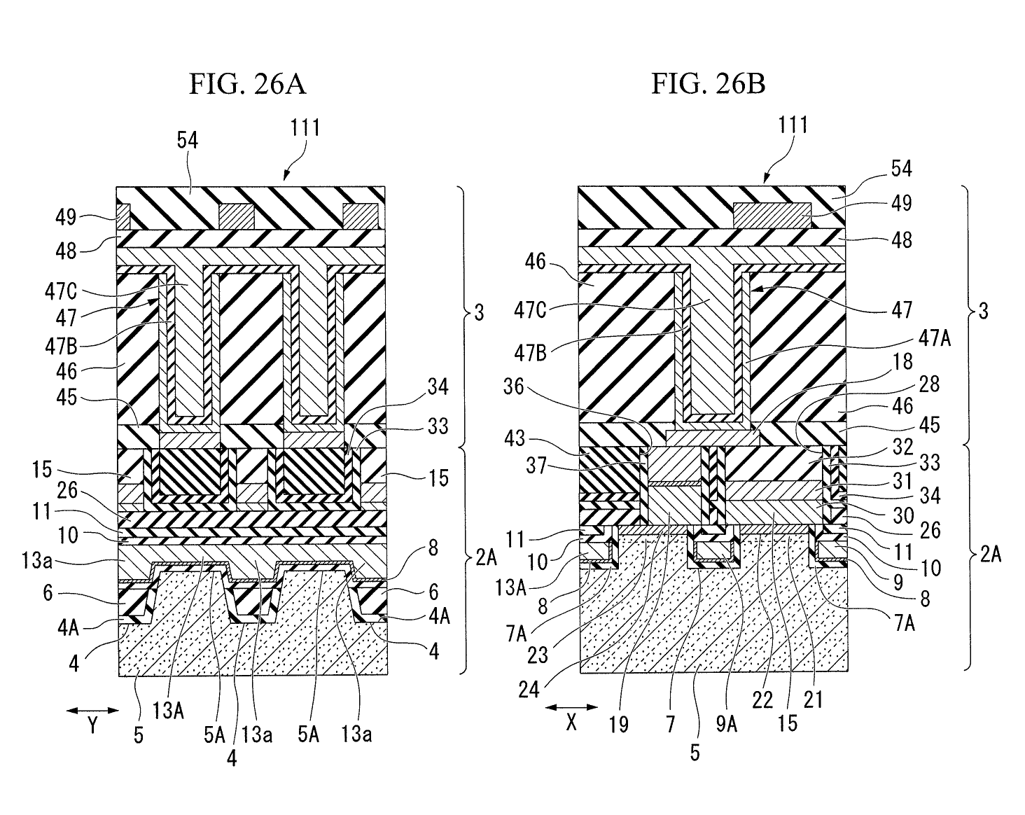

FIGS. 26A and 26B show an example of a structure of a semiconductor memory device including a saddle fin cell transistor instead of the semiconductor memory device 1 including the recess channel cell transistor described above with reference to FIGS. 1, 2A, and 2B.

A semiconductor memory device 111 according to the one embodiment of the present invention is substantially the same as the semiconductor memory device 1 according to the previous embodiment except for the cell transistor.

FIG. 26A is a cross-sectional view corresponding to line A-A′ of the semiconductor memory device 1 of FIG. 1, and FIG. 26B is a cross-sectional view corresponding to line B-B′ of the semiconductor memory device 1 of FIG. 1. The semiconductor memory device 111 according to the one embodiment of the present invention schematically includes a cell transistor forming region 2A and a capacitor forming region 3 shown in sectional structures of FIGS. 26A and 26B.

In the semiconductor memory device of the one embodiment of the present invention, an electrode of a side contact portion 13a, which contacts a side surface of the a high-concentration impurity diffusion layer 22, is formed in a buried line 13A to overlap element isolation trench 4. Thus, a convex portion 5A formed in the surface of a semiconductor substrate located between the side contact portion of electrodes 13a adjacent to each other in a Y direction of FIG. 26A is used as a channel region, unlike in the cell transistor of the semiconductor memory device 1 of the previous embodiment.

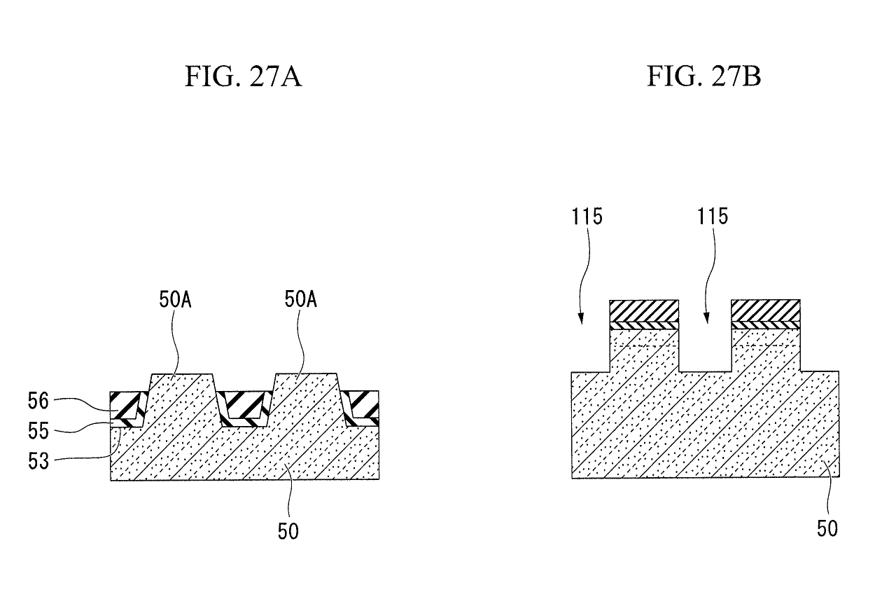

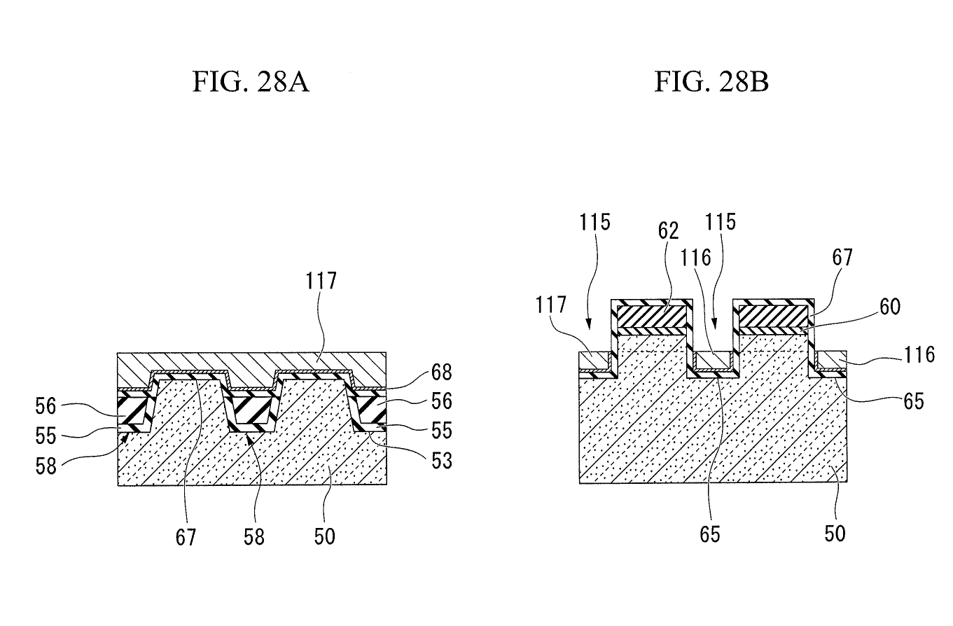

FIGS. 27A, 27B, 28A, and 28B are diagrams illustrating a process of fabricating a saddle fin cell transistor according to the one embodiment of the present invention.

Like the semiconductor memory device 1 according to the embodiment described above, according to the method described with reference to FIGS. 3A through 7B, a method of fabricating the semiconductor memory device 111 according to the one embodiment of the present invention includes the following processes. A silicon nitride film 62 for a mask and a carbon film 63 which is an amorphous carbon film are sequentially deposited on a semiconductor substrate 50 as shown in FIGS. 7A and 7B. A pattern for forming gate-electrode trenches, which are trenches, is formed as shown in FIGS. 7A and 7B. The semiconductor substrate 50 is dry etched as shown in FIGS. 27A and 27B, thereby forming trenches 115, which are gate-electrode trenches. As in the embodiment described above, the trenches 115 are formed in line-shaped patterns extending in a predetermined direction, which is the Y direction of FIG. 1. The predetermined direction intersects active regions K.

In the embodiment described above, the silicon film of the semiconductor substrate is etched to a greater depth than the element isolation trench as shown in FIGS. 8A and 8B. Conversely, in the one embodiment of the present invention, the element isolation trench 53 is etched to a greater depth than the trench 115 of the semiconductor substrate 50, so that a convex portion 50A can be formed on the semiconductor substrate 50 and used as a channel region of a cell transistor.

Afterwards, in the same manner as described in the embodiment with reference to FIGS. 9A and 9B, a gate insulating film 67, a titanium nitride film 68, and a tungsten film 69 may be formed and etched back. Hence, a buried word line 116 or a buried line 117 within the trench, which are the gate-electrode trench, is formed as shown in FIGS. 28A and 28B. Thus, subsequent processes of the process shown in FIGS. 11A and 11B are sequentially performed on the resultant structure of FIGS. 28A and 28B like in the embodiment described above, thereby fabricating the semiconductor memory device 111 having the sectional structure shown in FIGS. 26A and 26B.

In the semiconductor memory device 111 having the saddle fin cell transistor according to the one embodiment of the present invention, the channel region is a portion of the convex unit 50A formed in the surface of the semiconductor substrate 50. Also, the channel region is wider than in the semiconductor memory device 1 according to the embodiment described above. Accordingly, the saddle fin cell transistor according to the one embodiment of the present invention may allow the flow of a larger current as compared with the recess-type transistor according to the embodiment described above. The other structure is the same as that of the semiconductor memory device 1 described in the above-described embodiment, and the same effects can be realized.

Even in the semiconductor memory device 111 having the saddle fin type cell transistors shown in FIG. 26A and FIG. 26B, in the same manner as the semiconductor memory device 1 of the above-described embodiment, when the capacitance contact openings 36 are formed, the embedded insulating film 11 positioned thereunder comes into contact with the etching liquid. Accordingly, since the embedded insulating film 11 is formed of the boron-phosphorous silicate glass (BPSG) in the same manner as the above-described embodiment, the embedded insulating film 11 is not etched more than is required during etching, and it is possible to avoid making a short circuit between the embedded word lines 9A and the capacitance contact plugs 19 thereon.

As used herein, the following directional terms “forward, rearward, above, downward, vertical, horizontal, below, and transverse” as well as any other similar directional terms refer to those directions of an apparatus equipped with the present invention. Accordingly, these terms, as utilized to describe the present invention should be interpreted relative to an apparatus equipped with the present invention.

Furthermore, the particular features, structures, or characteristics may be combined in any suitable manner in one or more embodiments.

The terms of degree such as “substantially,” “about,” and “approximately” as used herein mean a reasonable amount of deviation of the modified term such that the end result is not significantly changed. For example, these terms can be construed as including a deviation of at least ±5 percents of the modified term if this deviation would not negate the meaning of the word it modifies.

It is apparent that the present invention is not limited to the above embodiments, but may be modified and changed without departing from the scope and spirit of the invention.

What is claimed is:

1. A method of forming a semiconductor device, the method comprising:
forming a groove in a semiconductor substrate;
forming a gate electrode in the groove;
forming a boron-phosphorus silicate glass film over the gate electrode; and
performing an etching process using the boron-phosphorus silicate glass film as an etching stopper for preventing the gate electrode from being removed.

2. The method according to claim 1, further comprising:
heating the boron-phosphorus silicate glass film.

3. The method according to claim 2, wherein heating the boron-phosphorus silicate glass film comprises heating the boron-phosphorus silicate glass film in a water vapor atmosphere.

4. The method according to claim 1, further comprising:
forming a first layered structure over the boron-phosphorus silicate glass film and the semiconductor substrate,
wherein performing the etching process comprises patterning the first layered structure.

5. The method according to claim 1, wherein foaming the first layered structure comprises forming a metal film of a first metal.

6. The method according to claim 5, wherein the gate electrode comprises the first metal.

7. The method according to claim 1, wherein forming the first layered structure comprises forming a nitride film.

8. The method according to claim 7, further comprising:
forming a liner film comprising nitride over the gate electrode before forming the boron-phosphorus silicate glass film.

9. The method according to claim 1, further comprising:
forming a second layered structure over the semiconductor substrate;
forming an opening in the second layered structure to expose a first portion of the semiconductor substrate; and
performing a cleaning process to clean the first portion using the boron-phosphorus silicate glass film as an etching stopper for protecting the gate electrode.

10. The method according to claim 1, further comprising:
planarizing a surface of the boron-phosphorus silicate glass film.

11. The method according to claim 10, wherein planarizing the surface of the boron-phosphorus silicate glass film comprises heating the boron-phosphorus silicate glass film.

12. The method according to claim 1, wherein the boron-phosphorus silicate glass film has a concentration in the range of boron from 10.5 mol % to 11.0 mol %, and
wherein the boron-phosphorus silicate glass film has a concentration in the range of phosphorus from 2.34 mol % to 2.76 mol %.

13. The method according to claim 12, wherein the boron-phosphorus silicate glass film has a sum of concentrations of boron and phosphorus, which is in the range from 14.3 mol % to 15.7 mol %.

14. The method according to claim 1, wherein forming the boron-phosphorus silicate glass film comprises performing a CVD process.

15. A method of forming a semiconductor device, the method comprising:
forming a boron-phosphorus silicate glass film over a semiconductor substrate;
forming a multi-layered structure comprising an oxide film over the boron-phosphorus silicate glass film and the semiconductor substrate;
forming an opening in the oxide film to expose a first portion of the semiconductor substrate and a second portion of the boron-phosphorus silicate glass film; and
performing a cleaning process to clean the first portion in a condition where the boron-phosphorus silicate glass film is lower in etching rate than the oxide film.

16. The method according to claim 15, further comprising:
forming a groove in the semiconductor substrate; and
forming a gate electrode in the groove before forming the boron-phosphorus silicate glass film over the gate electrode.

17. The method according to claim 16, wherein performing the cleaning process comprises the cleaning process using the boron-phosphorus silicate glass film as a stopper for protecting the gate electrode.

18. The method according to claim 15, further comprising:
forming a contact plug in the opening, the contact plug contacting the first portion.

19. The method according to claim 15, further comprising:
heating the boron-phosphorus silicate glass film before forming the multi-layered structure,
wherein heating the boron-phosphorus silicate glass film comprises heating the boron-phosphorus silicate glass film in a water vapor atmosphere.

20. A method of forming a semiconductor device, the method comprising:
forming a groove in the semiconductor substrate;
forming a gate electrode in the groove;
forming an insulating film in the groove and over the semiconductor substrate;
forming a boron-phosphorus silicate glass film in the groove and over the semiconductor substrate; and
planarizing a surface of the boron-phosphorus silicate glass film and a surface of the semiconductor substrate.
